(19) United States
(12) Patent Application Publication
(10) Pub. No.: US 2026/0157164 A1
(43) Pub. Date: Jun. 4, 2026

(54) NONVOLATILE MEMORY DEVICE AND ELECTRONIC SYSTEM INCLUDING THE SAME

(71) Applicant: Samsung Electronics Co., Ltd., Suwon-si (KR)

(72) Inventors: Kang Lib Kim, Suwon-si (KR); Dongjin Lee, Suwon-si (KR); Jaeduk Lee, Suwon-si (KR); Jaehoon Lee, Suwon-si (KR)

(21) Appl. No.: 19/404,798

(22) Filed: Dec. 1, 2025

(30) Foreign Application Priority Data
Dec. 3, 2024 (KR) 10-2024-0177929

(51) Int. Cl. H10W 20/20; H10B 41/10; H10B 41/27; H10B 41/35; H10B 43/10; H10B 43/27; H10B 43/35; H10B 80/00; H10D 80/30; H10W 20/41

(52) U.S. Cl. CPC H10W 20/2128; H10B 41/10; H10B 41/27; H10B 41/35; H10B 43/10; H10B 43/27; H10B 43/35; H10B 80/00; H10D 80/30; H10W 20/213; H10W 20/435

(57) ABSTRACT

An example of a non-volatile memory device includes a first substrate, a plurality of memory cell structures positioned on the first substrate; a second substrate facing in a first direction perpendicular to one surface of the first substrate, a first circuit element positioned on the second substrate, a third substrate positioned between the first substrate and the second substrate, a second circuit element positioned on the third substrate, and a through structure configured to include a dummy semiconductor pattern spaced apart from the third substrate within the third substrate, and a through electrode extending through the dummy semiconductor pattern in the first direction, wherein the through electrode has a first end connected to the first circuit element and a second end connected to at least one of the memory cell structures or the second circuit element.

### CROSS-REFERENCE TO RELATED APPLICATION

This application claims priority to and the benefit of Korean Patent Application No. 10-2024-0177929 filed at the Korean Intellectual Property Office on Dec. 3, 2024, the entire contents of which are incorporated herein by reference.

### BACKGROUND

Semiconductor memory devices may be broadly divided into volatile memory devices and nonvolatile memory devices. The volatile memory devices are memory devices in which stored data disappears when power is cut off, and examples include dynamic random access memory (DRAM) and a static random access memory (SRAM). Then, the nonvolatile memory devices are memory devices in which stored data is not lost even when power supply is cut off, and examples include a programmable ROM (PROM), an erasable PROM (EPROM), an electrically EPROM (EEPROM), and a flash memory device. Furthermore, in line with the recent trend toward higher performance and lower power consumption of semiconductor memory devices, next-generation semiconductor memory devices with nonvolatility, such as a magnetic random access memory (MRAM), a phase-change random access memory (PRAM), and a ferroelectric random access memory (FeRAM), are being developed. As high integration and high performance of non-volatile memory devices are demanded, various studies are being conducted using non-volatile memory devices with different characteristics.

### SUMMARY

Implementations attempt to provide a non-volatile memory device and an electronic system including the same, capable of improving reliability and reducing an overall size thereof.

An implementation of the present disclosure provides a non-volatile memory device including a first substrate, a plurality of memory cell structures positioned on the first substrate; a second substrate facing the first substrate in a first direction perpendicular to one surface of the first substrate, a first circuit element positioned on the second substrate, a third substrate positioned between the first substrate and the second substrate, a second circuit element positioned on the third substrate, and a through structure configured to include a dummy semiconductor pattern spaced apart from the third substrate within the third substrate, and a through electrode extending through the dummy semiconductor pattern in the first direction, wherein the through electrode has a first end connected to the first circuit element and a second end connected to at least one of the memory cell structures or the second circuit element.

An implementation of the present disclosure provides a non-volatile memory device including a first substrate, a gate stack structure configured to include an interlayer insulating layer and a gate electrode alternately stacked on a lower surface of the first substrate, channel structures configured to extend through the gate stack structure in a first direction Z perpendicular to a lower surface of the first substrate, a first bonding portion positioned below the channel structures and connected to at least one of the channel structures, a second substrate facing the first substrate in the first direction, a first circuit element positioned on an upper surface of the second substrate, a third substrate positioned between the first substrate and the second substrate, a second circuit element positioned on the third substrate, a second position positioned on the second circuit element and in contact with the first bonding portion, a through structure configured to include a dummy semiconductor pattern surrounded by the third substrate and spaced apart from the third substrate, and a through electrode extending toward an upper surface of the second substrate by extending through the dummy semiconductor pattern in the first direction, and a barrier pattern configured to extend through the third substrate in the first direction and surround a side surface of the through structure, wherein the through electrode has a first end connected to the first circuit element and a second end connected to at least one of the second bonding portions or the second circuit element.

An implementation of the present disclosure provides an electronic system including a main substrate, a non-volatile memory device on the main substrate, and a controller electrically connected to the non-volatile memory device on the main substrate, wherein the non-volatile memory device is configured to include a first substrate, a plurality of memory cell structures positioned on the first substrate, a second substrate facing the first substrate in a first direction perpendicular to one surface of the first substrate, a first circuit element positioned on the second substrate, a third substrate positioned between the first substrate and the second substrate, a second circuit element positioned on the third substrate, and a through structure configured to include a dummy semiconductor pattern surrounded by the third substrate and spaced apart from the third substrate, and a through electrode extending through the dummy semiconductor pattern in the first direction, wherein the through electrode has a first end connected to the first circuit element and a second end connected to at least one of the memory cell structures or the second circuit element.

According to the implementations, it may be possible to provide a non-volatile memory device and an electronic system including the same, capable of improving reliability and reducing an overall size thereof.

### BRIEF DESCRIPTION OF THE DRAWINGS

FIG. 1 illustrates a cross-sectional view showing a non-volatile memory device according to an implementation.

FIG. 2 illustrate an enlarged cross-sectional view showing an example of a channel structure included in the non-volatile memory device illustrated in FIG. 1.

FIG. 3 illustrates an enlarged cross-sectional view showing a portion “A” of FIG. 1.

FIG. 4 illustrates an enlarged cross-sectional view of a portion “B” of FIG. 3.

FIG. 5 illustrates a top plan view showing a region of a non-volatile memory device according to an implementation.

FIG. 6 illustrates an enlarged cross-sectional view of a portion “B” of FIG. 3.

FIG. 7 illustrates an enlarged cross-sectional view of a portion “B” of FIG. 3.

FIG. 8 illustrates an enlarged cross-sectional view of a portion “B” of FIG. 3.

FIG. 9 illustrates an enlarged cross-sectional view of a portion “B” of FIG. 3.

FIG. 10 illustrates a top plan view showing a region of a non-volatile memory device according to an implementation.

FIG. 11 illustrates a top plan view showing a region of a non-volatile memory device according to an implementation.

FIG. 12 illustrates a top plan view showing a region of a non-volatile memory device according to an implementation.

FIG. 13 illustrates a cross-sectional view taken along a line I3-I3′ of FIG. 12.

FIG. 14 to FIG. 24 illustrate process cross-sectional views for describing a manufacturing method for a non-volatile memory device according to an implementation.

FIG. 25 illustrates a partial cross-sectional view schematically showing a non-volatile memory device according to an additional implementation.

FIG. 26 illustrates a partial cross-sectional view schematically showing a non-volatile memory device according to an additional implementation.

FIG. 27 illustrates a partial cross-sectional view schematically showing a non-volatile memory device according to an additional implementation.

FIG. 28 schematically illustrates an electronic system including a non-volatile memory device according to an implementation.

FIG. 29 illustrates a schematic perspective view showing an electronic system including a non-volatile memory device according to an implementation.

FIG. 30 illustrates a schematic cross-sectional view of a semiconductor package according to an implementation.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

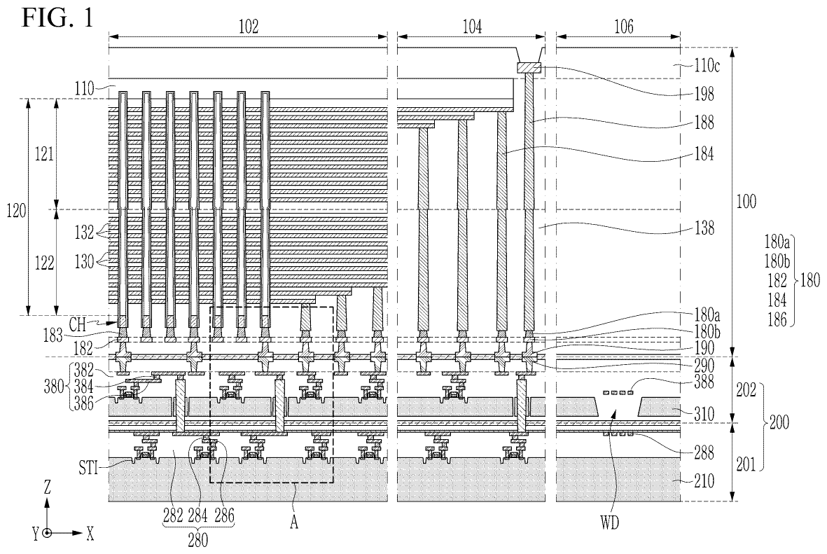

FIG. 1 to FIG. 3 illustrate top plan views and cross-sectional views for describing a manufacturing method for a non-volatile memory device according to an implementation.

FIG. 1 illustrates a cross-sectional view showing a non-volatile memory device according to an implementation,

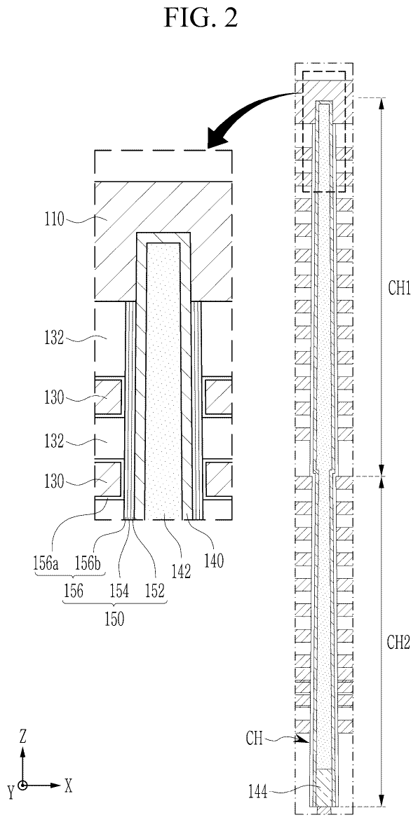

FIG. 2 illustrate an enlarged cross-sectional view showing an example of a channel structure included in the non-volatile memory device illustrated in FIG. 1, and

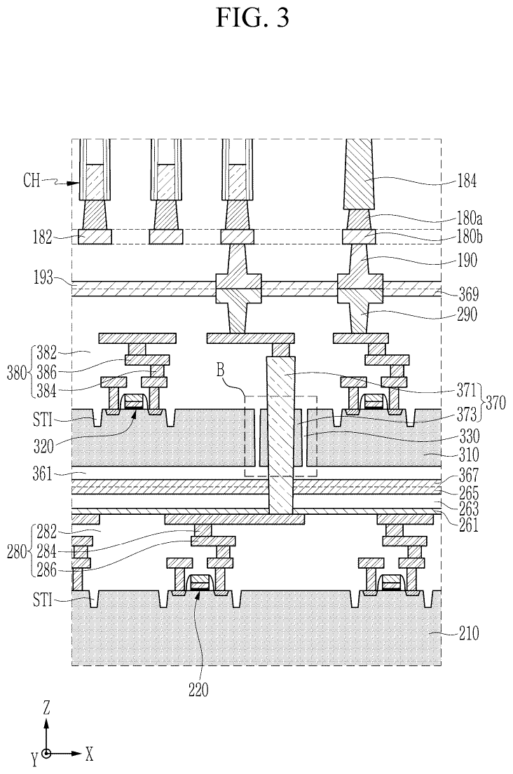

FIG. 3 illustrates an enlarged cross-sectional view showing a portion “A” of FIG. 1. For clear understanding, a gate contact portion 184 and a connection structure 188 are illustrated together in FIG. 1, but positions of the gate contact portion 184 and the connection structure 188 may be changed in various ways.

Referring to FIGS. 1 to 3, a nonvolatile memory device according to an implementation may include a cell region 100 including a memory cell structure, and a circuit region 200 including a peripheral circuit structure that controls an operation of the memory cell structure. In an implementation, the circuit region 200 may include a first circuit region 201, and a second circuit region 202.

In the implementation, the cell region 100 and the circuit region 200 may be bonded to each other to form a non-volatile memory device. The cell region 100 or the circuit region 200 may correspond to a semiconductor chip for a bonding semiconductor device included in a non-volatile memory device. In other words, the non-volatile memory device according to an implementation may be configured as a bonding vertical NAND (BV NAND) flash memory, but the implementations are not limited thereto. In the following, a description will be made on assumption that the non-volatile memory device according to an implementation is a bonding vertical NAND flash memory, but the implementations are not necessarily applicable only to the bonding vertical NAND flash memory, and may be applied to nonvolatile memory devices of various structures.

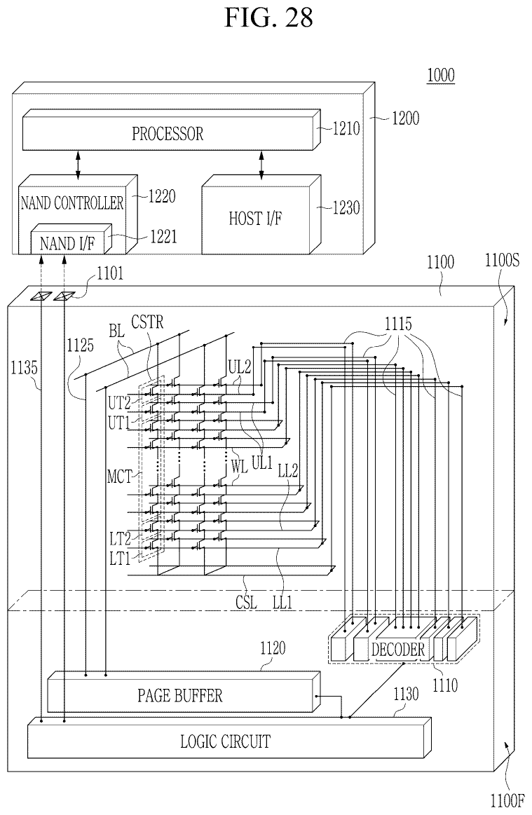

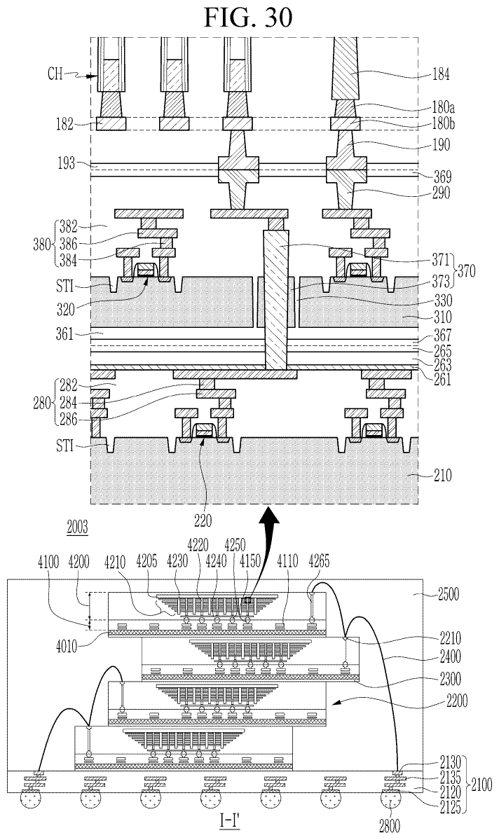

For example, the circuit region 200 and the cell region 100 may respectively be portions corresponding to a first structure 1100F and a second structure 1100S of a non-volatile memory device 1100 included in an electronic system 1000 illustrated in FIG. 28. Alternatively, the circuit region 200 and the cell region 100 may be portions including a first structure 4100 and a second structure 4200 of a semiconductor chip 2200 illustrated in FIG. 30, respectively.

The non-volatile memory device according to an implementation may include a first substrate 110, a plurality of memory cells positioned on the first substrate 110, a second substrate 210, a first circuit element 220 positioned on the second substrate 210, a third substrate 310, a second circuit element 320 positioned on the third substrate 310, and a through structure 370 extending through the third substrate 310. In an implementation, the first substrate 110 and a plurality of memory cells may be positioned in the cell region 100, the second substrate 210 and the first circuit element 220 may be positioned in a first circuit region 201, and the third substrate 310, the second circuit element 320, and the through-hole structure 370 may be positioned in a second circuit region 202.

In an implementation, the cell region 100 may be positioned on the circuit region 200. Accordingly, an area corresponding to the circuit region 200 does not need to be secured separately from the cell region 100, so an area of the non-volatile memory device 10 may be reduced.

In an implementation, the non-volatile memory device may be formed by bonding the cell region 100 to the circuit region 200 after the cell region 100 is formed separately from the circuit region 200. For example, the cell region 100 may be bonded to the circuit region 200 by a chip-to-chip (C2C) bonding process, a chip-to-wafer bonding process, or a wafer-to-wafer bonding process using a hybrid bonding method. In this way, as the cell region 100 and the circuit region 200 are formed through separate processes, it may be possible to prevent the circuit region 200 from being affected when the cell region 100 is formed.

The cell region 100 may include a first substrate 110, a gate stack structure 120, a channel structure CH, a first wiring portion 180, and a first bonding portion 190 positioned on the first wiring portion 180. In this way, the cell region 100 corresponding to a semiconductor chip for a bonding semiconductor device may include a first substrate 110 corresponding to a substrate, a first wiring portion 180 corresponding to a wiring portion positioned on the substrate, and a first bonding portion 190 corresponding to a bonded portion positioned on the wiring portion.

At least a portion of the first substrate 110 may function as a common source line. Although not explicitly shown in FIG. 1, in an implementation, a source contact portion may be electrically connected to the common source line. Unlike in shown in FIG. 1, a source connector may be provided that is connected to the first substrate 110 by a through via extending through an outer insulating layer 110c on an outer surface of the first substrate 110. In this case, the source contact portion may be connected to the source connector either through a through via or directly. However, the implementation is not limited thereto, and an electrical connection structure of the source contact portion and the common source line may be modified in various ways.

The cell region 100 may include a cell array region 102 and a connection region 104. The cell region 100 may be provided with a memory cell structure including at least a gate stack structure 120 and a channel structure CH positioned in the cell array region 102. A structure for connecting the memory cell structure to the circuit area 200 or an external circuit may be positioned in the cell array area 102 and/or the connection region 104.

In an implementation, the first substrate 110 may include a semiconductor layer including a semiconductor material. For example, the first substrate 110 may be a semiconductor substrate made of a semiconductor material or may be a substrate on which a semiconductor layer is disposed on a base substrate. For example, the first substrate 110 may be formed of silicon, germanium, silicon-germanium, silicon on insulator, or germanium on insulator. In this case, the first substrate 110 may include an n-type semiconductor layer doped with an n-type dopant such as phosphorus (P) or arsenic (As) and/or a p-type semiconductor layer doped with a p-type dopant such as boron (B) or gallium (Ga). As another example, the first substrate 110 may include a supporting member including an insulating layer or insulating material. In this case, after the cell region 100 is bonded to the circuit region 200, the semiconductor substrate provided in the cell region 100 may be removed, and then a support member including an insulating layer or insulating material may be formed. The implementation is not limited to a material of the first substrate 110, a conductive type or material of the dopant doped into the semiconductor layer, etc.

The gate stack structure 120 may include cell insulating layers 132 and gate electrodes 130 that are alternately stacked on one surface (lower surface of FIG. 1) of the first substrate 110. The channel structure CH may extend in an extension direction that extend through the gate stack structure 120 to intersect the first substrate 110. For example, the extension direction of the channel structure (CH) may correspond to a Z-axis direction of the drawing, i.e., a direction intersecting the first substrate (110) (e.g., a vertical direction perpendicular to the first substrate 110).

The gate electrode 130 may include various conductive materials. For example, the gate electrode 130 may include a metal material such as tungsten (W), copper (Cu), aluminum (Al), polycrystalline silicon, a metal nitride (e.g., titanium nitride (TiN), tantalum nitride (TaN), etc.), or a combination thereof. The cell insulating layer 132 may include various insulating materials. For example, the cell insulating layer 132 may include a silicon oxide, a silicon nitride, a silicon oxynitride, a low-k material having a lower dielectric constant than the silicon oxide, or a combination thereof.

The channel structure CH may include a channel layer 140 and a gate dielectric layer 150 disposed on the channel layer 140 between the gate electrode 130 and the channel layer 140. The gate dielectric layer 150 positioned between the gate electrode 130 and the channel layer 140 may include a tunneling layer 152, a charge storage layer 154, and a blocking layer 156 sequentially disposed on the channel layer 140.

The channel structure CH may further include a core insulating layer 142 positioned inside the channel layer 140, but as another example, the core insulating layer 142 may not be provided. The channel structure CH may further include a channel pad 144 disposed on the channel layer 140 and/or the gate dielectric layer 150. The channel pad 144 may be positioned to cover an upper surface (bottom surface of FIG. 1) of the core insulating layer 142 and to be electrically connected to the channel layer 140.

Each channel structure CH forms one memory cell string, and a plurality of channel structures CH may be spaced apart from each other while forming rows and columns in a plan view. For example, the channel structures CH may be arranged in various forms such as a lattice form or a zigzag form in a plan view. The channel structures CH may each have a columnar shape. For example, when the channel structure CH is viewed in a cross-sectional view, it may have an inclined side surface such that its width narrows as it approaches the first substrate 110 according to an aspect ratio. However, the implementation is not limited thereto, and the arrangement, structure, and form of the channel structure CH may be variously modified.

The first channel layer 140 may include a semiconductor material, e.g., polycrystalline silicon. The core insulating layer 142 may include various insulating materials. For example, the core insulating layer 142 may include a silicon oxide, a silicon nitride, a silicon oxynitride, or a combination thereof. The channel pad 144 may include a conductive material, e.g., polycrystalline or single crystal silicon doped with an impurity.

The tunneling layer 152 may include an insulating material capable of tunneling charges (e.g., a silicon oxide, a silicon nitride, etc.). The charge storage layer 154 is used as a data storage region, and the charge storage layer 154 may include polycrystalline silicon, a silicon nitride, or the like. The blocking layer 156 may include an insulating material capable of preventing an undesirable flow of charges into the gate electrode 130. For example, the blocking layer 156 may include a silicon oxide, a silicon nitride, a silicon oxynitride, a high-k material having a higher dielectric constant than the silicon oxide, or a combination thereof. In an implementation, the blocking layer 156 may include a first blocking layer 156a including a portion extending horizontally along the gate electrode 130, and a second blocking layer 156b extending vertically between the first blocking layer 156a and the charge storage layer 154.

However, the implementation is not limited to the material, structure, etc. of the channel layer 140, the core insulating layer 142, the channel pad 144, or the gate dielectric layer 150.

In an implementation, the gate stack structure 120 may include a plurality of gate stack portions 121 and 122 sequentially stacked on the first substrate 110. Then, a number of stacked gate electrodes 130 may be increased, so a number of memory cells may be increased with a stable structure. FIG. 2 illustrates a gate stacking structure 120 including first and second gate stacking portions 121 and 122. However, the implementation is not limited thereto, and the gate stacking structure 120 may include one or more gate stacking portions.

As described above, when a plurality of gate stack portions 121 and 122 are provided, a plurality of channel portions CH1 and CH2 each having a form in which the channel structure CH extends through each of the gate stack portions 121 and 122 and are connected to each other may be provided. Each of the channel portions CH1 and CH2 has an inclined side surface such that a width becomes narrower as it approaches the first substrate 110 according to the aspect ratio when viewed in cross-section, and a bent portion due to a width difference may be provided at a connected portion of the channel portions CH1 and CH2. As another example, the channel portions CH1 and CH2 may have inclined side surfaces that are continuously connected without any bent portions. In FIG. 3, it is illustrated that the gate dielectric layer 150, the channel layer 140, and the core insulating layer 142 of the channel portions CH1 and CH2 extend from each other to have an integral structure. As another example, the gate dielectric layer 150, the channel layer 140, and the core insulating layer 142 of the channel portions CH1 and CH2 may be formed separately from each other and electrically connected to each other, or a separate channel pad may be additionally provided at a connection portion of the channel portions CH1 and CH2. In this way, the implementation is not limited to the form of the channel portions CH1 and CH2.

A connecting region 104 and a first wiring portion 180 may be provided to connect the gate stack structure 120 and the channel structure CH provided in the cell array region 102 to the circuit region 200 or an external circuit. The connecting region 104 may be positioned around the cell array region 102 and a portion of the first wiring portion 180 may be positioned.

In an implementation, the first wiring portion 180 may include all members electrically connecting the gate electrode 130, the channel structure CH, and the first substrate 110 to the circuit region 200 or an external circuit. For example, the first wiring portion 180 may include a bitline 182, a gate contact portion 184, a connection structure 188, a contact via 180a connected to each thereof, and a connection wire 180b connecting these.

The bitline 182 may extend in a second direction (Y-axis direction in the drawing) intersecting the first direction (X-axis direction in the drawing) in which the gate electrode 130 extends, and may be electrically connected to the channel structure CH, e.g., the channel pad 144.

The gate electrodes 130 may be extended and positioned in the first direction (X-axis direction in the drawing) in the connecting region 104, and the extended lengths of the gate electrodes 130 in the connecting region 104 may sequentially decrease as a distance from the first substrate 110 increases. For example, the gate electrodes 130 may have a step shape in one direction or multiple directions in the connection region 104. In the connection region 104, a plurality of gate contacts 184 may be electrically connected to a plurality of gate electrodes 130 extending through an interlayer insulating layer 138 to the connection region 104.

Although not explicitly shown in FIG. 1, a source contact portion may be electrically connected to the first substrate 110 forming at least a portion of the common source line. The connection structure 188 may be electrically connected to an input/output pad 198 provided in the cell region 100. Unlike what is shown in FIG. 1, the circuit region 200 may be provided with a separate input/output pad 198.

The connection wire 180b may be positioned in the cell array region 102 and/or the connection region 104. The bitline 182, the gate contact portion 184, the source contact portion, and/or the connection structure 188 may be electrically connected to a connection wire 180b. For example, the bitline 182, the gate contact portion 184, the source contact portion, and/or the connection structure 188 may be electrically connected to the connection wire 180b through the contact via 180a. The connection wire 180b may include a plurality of connecting wiring layers spaced apart with the interlayer insulating layer 138 therebetween and connected to form a desired path by contact vias.

In FIG. 1, the connection wire 180b is provided as a single layer positioned on a same plane as that of the bitline 182, and the cell insulating layer 132 is positioned in a portion other than the first wiring portion 180. However, this is only briefly illustrated for convenience. Accordingly, the connecting wire 180b may include multiple wiring layers, and may further include contact vias for electrical connection with the bitline 182 and/or the gate contact portion 184.

In the first circuit region 201, the second substrate 210 and the first circuit element 220 positioned on the second substrate 210 may be positioned. In an implementation, the first circuit elements 220 positioned on the second substrate 210 may be positioned in the first circuit region 201. The second substrate 210 may further include a device isolation pattern STI to isolate each of the first circuit elements 220 from other first circuit elements 220.

The second substrate 210 may be a semiconductor substrate including a semiconductor material. For example, the second substrate 210 may be a semiconductor substrate made of a semiconductor material or may be a semiconductor substrate on which a semiconductor layer is formed on a base substrate. For example, the second substrate 210 may be formed of monocrystalline or polycrystalline silicon, epitaxial silicon, germanium, silicon-germanium, silicon-on-insulator (SOI), or germanium-on-insulator (GOI).

In an implementation, the first circuit element 220 positioned on the second substrate 210 may include various circuit elements that control an operation of second circuit elements (320) provided in the second circuit region 202 or a memory cell structure provided in the cell region 100. In an implementation, the first circuit element 220 may include low voltage elements. When the non-volatile memory device according to an implementation operates, a lower operating voltage may be applied to the first circuit element 220 compared to the second circuit element 320. In an implementation, the first circuit element 220 may be connected to a first external power source, and the first power source may have a relatively low voltage. For example, the first power source may have a lower voltage than the second power source connected to the second circuit element 320.

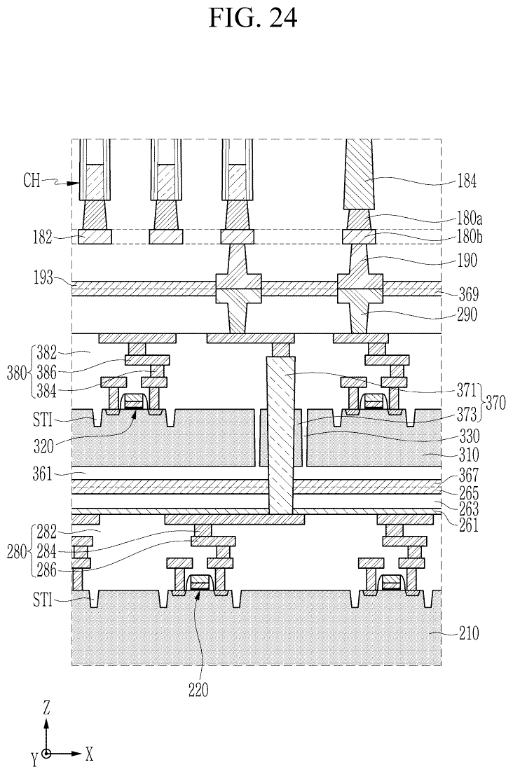

In an implementation, the first circuit element 220 may have a lower breakdown voltage compared to the second circuit element 320. For example, the first circuit element 220 may constitute at least a portion of a peripheral circuit structure of a logic circuit (reference numeral 1130 of FIG. 24) or a page buffer (reference numeral 1120 of FIG. 28).

The first circuit element 220 may include, e.g., a plurality of transistors, according but the implementation is not limited thereto. The first circuit element 220 may include not only active elements such as transistors, but also passive elements such as capacitors, resistors, and inductors.

A non-volatile memory device according to an implementation may further include a second wiring portion 280 positioned on the second substrate 210, interlayer insulating layers 261 and 263 covering the second wiring portion 280, and an interface insulating layer 265.

The second wiring portion 280 positioned on a second substrate 210 may be electrically connected to the first circuit element 220. In an implementation, the second wire portion 280 may include a plurality of wiring layers 286 spaced apart with a wiring insulating layer 282 provided therebetween and connected to form a desired path by the contact via 284. The wiring layer 286 or the contact via 284 may include various conductive materials, and the wiring insulating layer 282 may include various insulating materials. For example, the wiring capping layer 282 may include at least one of a silicon oxide, a silicon nitride, or a silicon oxynitride.

Interlayer insulating layers 261 and 263 may be positioned on the second wiring portion 280. The interlayer insulating layers 261 and 263 may cover at least some regions of the wiring insulating layer 282, the contact via 284, and the wiring layer 286. The interlayer insulating layers 261 and 263 may include an insulating material. For example, the interlayer insulating layers 261 and 263 may include at least one of a silicon oxide (SiO₂), a silicon nitride (SiN_{X}), or a silicon oxynitride (SiON). The interlayer insulating layers 261 and 263 may include different insulating materials, or may include a same insulating material.

The interface insulating layer 265 may be positioned on the interlayer insulating layer 263. The interface insulating layer 265 may be positioned at an interface between the first circuit region 201 and the second circuit region 202. The interface insulating layer 265 may include an insulating material. For example, the interface insulating layer 263 may include at least one of a silicon oxide (SiO₂), a silicon nitride (SiN_{X}), or a silicon oxynitride (SiON).

In the second circuit 202, the third substrate 310, the second circuit elements 320 positioned on one surface of the third substrate 310, and the through structure 370 extending through the third substrate 310 may be positioned. In an implementation, the second circuit elements 320 positioned on the third substrate 310 may be positioned in the second circuit region 202. The third substrate 310 may further include a device isolation pattern STI to isolate each of the second circuit elements 320 from other second circuit elements 320. In the implementation, at least a portion of the through structure 370 may be positioned in the first circuit region 201. Specifically, referring to FIG. 1 and FIG. 3, a first end of a through electrode 371 may extend toward an upper surface of the second substrate 210, and accordingly, a region of a lower portion of the through electrode 371 may be positioned in the first circuit region 201.

The third substrate 310 may be a semiconductor substrate. A composition and a material of the third substrate 310 may be identical or similar to those of the second substrate 210 described above, so a detailed description will be omitted.

The second circuit element 320 positioned on the third substrate 310 may include various circuit elements that control the operation of the memory cell structure provided in the cell region 100. In an implementation, the second circuit element 320 may include high voltage elements. The high voltage elements may be elements designed to have relatively high breakdown voltages. When the non-volatile memory device according to an implementation operates, a higher operating voltage may be applied to the second circuit element 320 compared to the first circuit element 220. In an implementation, the second circuit element 320 may be connected to a second external power source, and the second power source may have a relatively high voltage. For example, the second power source may have a higher voltage than that of the first power source connected to the first circuit element 220.

In an implementation, the second circuit element 320 may have a higher breakdown voltage compared to the first circuit element 220. As an example, the second circuit element 320 may form at least a portion of a peripheral circuit structure of a decoder circuit (reference numeral 1110 of FIG. 28) and/or a page buffer (reference numeral 1120 of FIG. 28).

The second circuit element 320 may include, e.g., a plurality of transistors, according but the implementation is not limited thereto. The second circuit element 320 may include not only active elements such as transistors, but also passive elements such as capacitors, resistors, and inductors.

A non-volatile memory device according to an implementation may further include a third wiring portion 380 positioned on an upper surface of the third substrate 310, an interface insulating layer 369 and a second bonding portion 290 positioned on the third wiring portion 380, an interlayer insulating layer 361 and an interface insulating layer 367 positioned on a lower surface of the third substrate 310.

The third wiring portion 380 positioned on the third substrate 310 may be electrically connected to the second circuit element 320. In an implementation, the third wire portion 380 may include a plurality of wiring layers 386 spaced apart with a wiring insulating layer 382 provided therebetween and connected to form a desired path by the contact via 384. The wiring layer 386 or the contact via 384 may include various conductive materials, and the wiring insulating layer 382 may include various insulating materials. For example, the wiring capping layer 382 may include at least one of a silicon oxide, a silicon nitride, or a silicon oxynitride.

The interlayer insulating layer 361 and the interface insulating layers 367 and 369 may be similar to the interlayer insulating layers 261 and 263 and the interface insulating layer 265 described above, so a detailed description will be omitted.

A non-volatile memory device according to an implementation may include a first junction 190 and an interface insulating layer 193 positioned in the cell region 100 adjacent to the circuit region 200, and a second binding portion 290 and the interface insulating layer 369 positioned in the circuit region 200 adjacent to the cell region 100. In an implementation, the cell region 100 and the circuit region 200 may be bonded by bonding the first bonding portion 190 and the second bonding portion 290 to form a non-volatile memory device. At least a portion of the first bonding portion 190 may be electrically connected to the first wiring portion 180.

Specifically, the first bonding portion 190 may be connected to at least one of the bitline 182 or the connection wire 180b. The first bonding portion 190 may be connected to the channel structure CH through the bitline 182, or may be connected to the gate contact portion 184 or the connection structure 188 through the connection wire 180b. Unlike what is shown in FIG. 1, the first bonding portion 190 may also be connected to the bitline 182 via the connection wire 180b.

The second bonding portion 290 may be connected to the first circuit element 220. Specifically, the second bonding portion 290 may be connected to the through electrode 371 extending through the third substrate 310 through the contact via 384 or a wiring layer 386, and the through electrode 371 may be connected to the first circuit element 220 through the second wiring portion 280.

The second bonding portion 290 may be connected to the second circuit element 320. Specifically, the second bonding portion 290 may be connected to the second circuit element 320 through the contact via 384 or the wiring layer 386.

In an implementation, the bitline 182, the gate electrode 130, the first substrate 110 connected to the channel structure CH may be electrically connected to the first circuit element 220 of the first circuit region 201 or the second circuit element 320 of the second circuit region 202 by means of the first wiring portion 180, the first bonding portion 190, the second bonding portion 290, the second wiring portion 280, the through electrode 371, and the third wiring portion 380.

The through structure 370 may be positioned within the third substrate 310. The through structure 370 may include a dummy semiconductor pattern 373 surrounded by the third substrate 310 and positioned spaced apart from the third substrate 310, and a through electrode 371 extending through the dummy semiconductor pattern 373 in the third direction Z. The through structure 370 may electrically connect the first circuit elements 220 positioned on the second substrate 210 to components positioned on the first substrate 110 and/or the third substrate 310 through the through electrode 371. For example, referring to FIGS. 1 and 3, the first circuit element 220 may be connected to the second circuit element 320 positioned on the third substrate 310 through the through electrode 371. For example, the first circuit element 220 may be connected to the second bonding portion 290 positioned in the second circuit region 202 through the through electrode 371, and may be connected to the channel structure CH, the gate contact 184, the connection structure 188, and/or the source contact within the cell region 100 through the first bonding portion 190 connected to the second bonding portion 290.

The through electrode 371 may extend toward an upper surface of the second substrate 210 by extending through the dummy semiconductor pattern 373 that is surrounded by the third substrate 310 and positioned apart from the third substrate 310 in the third direction Z. A first end of the through electrode 371 extending toward the upper surface of the second substrate 210 may be connected to the contact via 284 or the wiring layer 286. The through electrode 371 may be connected to the first circuit element 220 through the contact via 284 or the wiring layer 286. A second end of the through electrode 371 positioned on the third substrate 310 may be connected to the wiring layer 386 or the contact via 384. The through electrode 371 may be connected to the second circuit element 320 through the wiring layer 386 or the contact via 384. Alternatively, the through electrode 371 may be connected to at least one of a plurality of memory cells positioned in the cell region 100 through the bonding portions 190 and 290 connected to the wiring layer 386 or the contact via 384. Specifically, the through electrode 371 may be connected to the gate stack structure 120 and/or the channel structure CH positioned in the cell region 100 through the bonding portions 190 and 290 connected to the wiring insulating layer 382 or the contact via 384.

The through electrode 371 may include a conductive material. For example, the through electrode 371 may include a metal material such as tungsten (W), copper (Cu), aluminum (Al), polycrystalline silicon, a metal nitride (e.g., titanium nitride (TiN), tantalum nitride (TaN), etc.), or a combination thereof.

The dummy semiconductor pattern 373 may be positioned within the third substrate 310 and spaced apart from the third substrate 310. The dummy semiconductor pattern 373 may be electrically isolated from the third substrate 310. The dummy semiconductor pattern 373 may not include a portion in contact with the third substrate 310. In an implementation, the dummy semiconductor pattern 373 may have substantially a same thickness as that of the third substrate 310. An upper surface of the dummy semiconductor pattern 373 may be positioned at substantially a same level as that of an upper surface of the third substrate 310. A lower surface of the dummy semiconductor pattern 373 may be positioned at substantially a same level as that of a lower surface of the third substrate 310.

Some areas of the dummy semiconductor pattern 373 may be penetrated by the through electrode 371. Referring to FIGS. 1 and 3, the dummy semiconductor pattern 373 may be penetrated in the third direction Z by the through electrode 371. The dummy semiconductor pattern 373 may surround at least a portion of a side surface of the through electrode 371. The dummy semiconductor pattern 373 may surround the side surface of the through electrode 371 in a region where the third substrate 310 and the through electrode 371 overlap in a horizontal direction (e.g., the first direction X or the second direction Y). An inner surface of the dummy semiconductor pattern 373 may be in contact with the through electrode 371 in a region where the third substrate 310 and the through electrode 371 overlap in the horizontal direction. An outer surface of the dummy semiconductor pattern 373 may be in contact with a barrier pattern 330 to be described later.

The dummy semiconductor patterns 373 may include an semiconductor material. For example, the dummy semiconductor pattern 373 may be formed of monocrystalline or polycrystalline silicon, epitaxial silicon, germanium, silicon-germanium, silicon-on-insulator (SOI), or germanium-on-insulator (GOI). In an implementation, the dummy semiconductor pattern 373 may include a same material as that of the third substrate 310. This may be due to process characteristics in which the dummy semiconductor pattern 373 is formed by etching a portion of the third substrate 310 and separating it from the third substrate 310. However, the implementation is not limited thereto, and the dummy semiconductor pattern 373 may include a different material from that of the third substrate 310.

A non-volatile memory device according to an implementation may further include a barrier pattern 330 positioned between the third substrate 310 and the dummy semiconductor pattern 373. The barrier pattern 330 may surround an outer surface of the dummy semiconductor pattern 373 between the third substrate 310 and the dummy semiconductor pattern 373. For example, the barrier pattern 330 may be formed by etching a portion of the third substrate 310 such that the third substrate 310 penetrates in the third direction Z to form the dummy semiconductor pattern 373, and then filling a space between the dummy semiconductor pattern 373 and the third substrate 310 with an insulating material. The dummy semiconductor pattern 373 and the third substrate 310 may be horizontally separated from each other by the barrier pattern 330. In an implementation, a distance in the horizontal direction (e.g., the first direction X or the second direction Y) between the dummy semiconductor pattern 373 and the third substrate 310 may be greater than 0 and less than or equal to about 500 nm. Alternatively, the distance along the horizontal direction (e.g., the first direction X or the second direction Y) between the dummy semiconductor pattern 373 and the third substrate 310 may be greater than 0 and less than or equal to about 200 nm.

In an implementation, the barrier pattern 330 may include an insulating material. For example, the barrier pattern 330 may include at least one of a silicon oxide (SiO₂), a silicon nitride (SiN_{X}), or a silicon oxynitride (SiON). In an implementation, the barrier pattern 330 may include a same insulating material as that of the wiring insulating layer 382, but the present disclosure is not limited thereto.

In the case of a non-volatile memory device according to an implementation, the through electrode 371 may be electrically separated from the third substrate 310 by the barrier pattern 330 surrounding the dummy semiconductor pattern 373. In this case, an electrical signal flowing through the through electrode 371 may be prevented from flowing to the second circuit element 320 through the third substrate 310, and thus reliability of the non-volatile memory device may be improved.

In addition, according to an implementation, the through electrode 371 extending through the third substrate 310 may be formed in a narrow area through a simple process, thereby improving reliability of a process for manufacturing a non-volatile memory device and reducing a size of the memory device. This will be described later.

A non-volatile memory device according to an implementation may further include an outer region 106 positioned at a first side of the connection region 104. The outer region 106 may be a region that does not exist in a final product of the non-volatile memory device according to an implementation. For example, in a final stage of the manufacturing process of a non-volatile memory device, the outer region 106 may be separated from other regions (e.g., the cell array region 102 and the connection region 104) by a scribing process.

In an implementation, a plurality of align keys 288 and 388 may be positioned in the outer region 106. The align keys may be a pattern used when alignment is required between substrates 110, 210, and 310 in a process of bonding the substrates 110, 210, and 310 among manufacturing processes of a non-volatile memory device according to an implementation, or in a photo process, or when alignment is required between a photomask and the substrates 110, 210, and 310. In FIG. 1, the align keys 288 and 388 positioned in the circuit region 200 are illustrated, but this is merely an example for convenience of description, and the align keys may also be positioned in the cell region 100.

Referring to FIG. 1, the first align key 288 may be positioned on a portion of the outer region 106 on the second substrate 210, and the second align key 388 may be positioned on a portion of the outer region 106 on the third substrate 310. The first align key 288 and the second align key 388 may overlap each other in the third direction Z. An align window WD may be positioned between the first align key 288 and the second align key 388. The align window WD may be a portion of a substrate that is removed and filled with an insulating material to align two substrates. In FIG. 1, the align window WD may be a region where some regions of the third substrate 310 have been removed by the etching process. In an implementation, a portion from which the third substrate 310 has been removed may be filled with the wiring insulating layer 382. In an implementation, the second substrate 210 and the third substrate 310 may be aligned by positioning the first align key 288 and the second align key 388 to overlap each other through the align window WD.

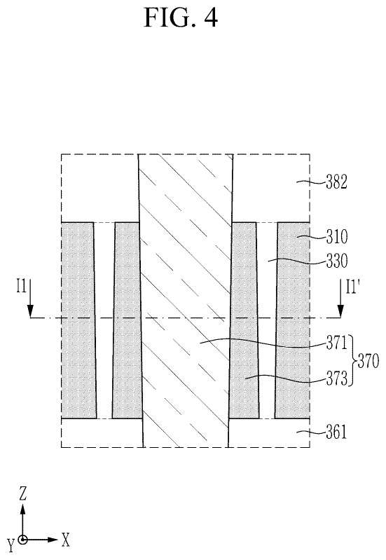

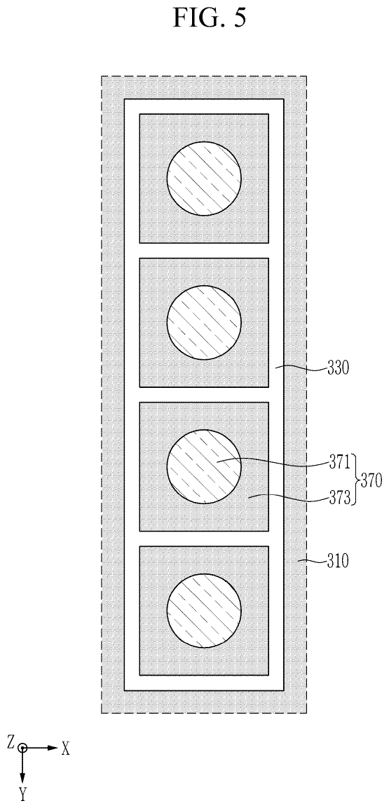

FIGS. 4 and 5 illustrate views for describing the through structure 370 according to an implementation. Specifically, FIG. 4 illustrates an enlarged cross-sectional view of a portion “B” of FIG. 3, and FIG. 5 illustrates a top plan view showing a region of a non-volatile memory device according to an implementation.

FIG. 5 illustrates 5 illustrates a top plan view at the level along line I1-I1′ of FIG. 4.

In a non-volatile memory device according to an implementation, the through structure 370 may include a plurality of through electrodes 371 positioned adjacent to each other in a horizontal direction. Referring to FIGS. 4 and 5, four through electrodes 371 are illustrated, but a number of through electrodes 371 positioned adjacent to each other is not limited. In FIGS. 4 and 5, a plurality of through electrodes 371 are illustrated as being aligned and spaced apart from each other along the second direction Y, but positions or directions in which the through electrodes 371 are aligned, or the arrangement forms, are not limited. For example, the through electrodes 371 may be aligned in the first direction X or may be aligned spaced apart from each other in a diagonal direction between the first direction X and the second direction Y. For example, the through electrodes 371 may be arranged in a matrix shape or a hexagonal shape within the third substrate 310.

In an implementation, the through structure 370 may include a plurality of dummy semiconductor patterns 373 and a through electrode 371 extending through each of the dummy semiconductor patterns 373 in a third direction (Z). Each of the dummy semiconductor patterns 373 may surround a portion of a side surface of the through electrodes 371 that extend through the pattern in the third direction Z. Each of the dummy semiconductor patterns 373 may have its inner surface in contact with the through electrodes 371 extending through the pattern in the third direction Z.

Referring to FIG. 5, the through electrode 371 is illustrated as having a circular plane shape, but this is an example, and the through electrode 371 may have various planar shapes. For example, the through electrode 371 may have a planar shape of an ellipse, triangle, square, or other polygon.

The dummy semiconductor patterns 373 may be positioned horizontally spaced apart from other adjacent dummy semiconductor patterns 373. In an implementation, the barrier pattern 330 may be positioned between two adjacent dummy semiconductor patterns 373. The dummy semiconductor patterns 373 may be electrically separated from each other by the barrier pattern 330. The through electrodes 371 may be electrically separated from each other by the barrier pattern 330 positioned between the dummy semiconductor patterns 373.

Referring to FIG. 5, the dummy semiconductor pattern 373 is illustrated as having a square shape in planar shape, but this is an example, and the dummy semiconductor pattern 373 may have various planar shapes. For example, the through electrode 371 may have a circular or oval planar shape, or other polygonal shape such as a rectangle, triangle, or pentagon.

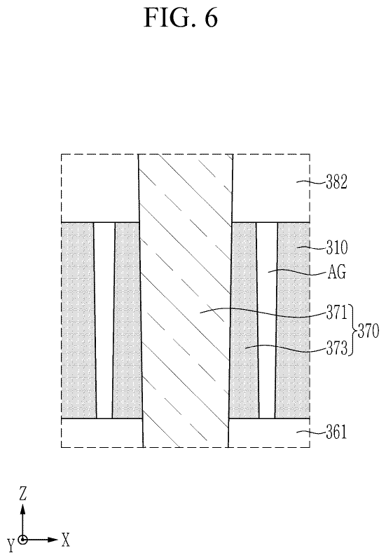

FIG. 6 illustrates a region of a non-volatile memory device according to an implementation. Specifically, FIG. 6 illustrates an enlarged cross-sectional view showing a portion “A” of FIG. 1. The non-volatile memory device illustrated in FIG. 6 has many similarities to the previous implementations, so the following description focuses mainly on the differences from the previous implementations. The non-volatile memory device illustrated in FIG. 6 may differ in some respects from the previous implementations in that it includes an air gap.

Referring to FIG. 6, in a non-volatile memory device according to an implementation, an air gap AG may be positioned between the dummy semiconductor pattern 373 and the third substrate 310. The air gap AG may refer to an empty space positioned between one layer and another. For example, the air gap AG may include air, or a gas used in the manufacturing process of non-volatile memory devices. In an implementation, the air gap AG may be positioned between the third substrate 310 and the dummy semiconductor pattern 373 in a region where the third substrate 310 and the dummy semiconductor pattern 373 overlap in the horizontal direction. The third substrate 310 and the dummy semiconductor pattern 373 may be separated from each other by the air gap AG. The air gap AG may surround the side surface of the dummy semiconductor pattern 373. In other words, in a case of a non-volatile memory device according to an implementation, the barrier pattern 330 described with reference to FIGS. 1 to 5 may be replaced with the air gap AG.

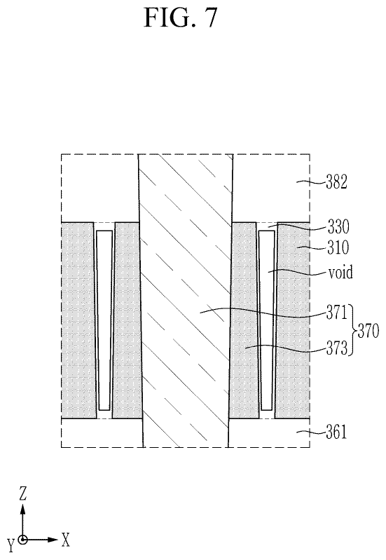

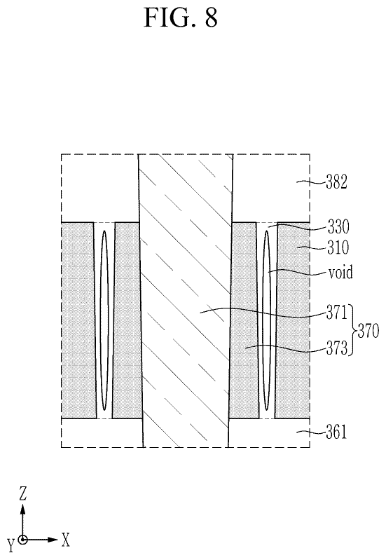

FIG. 7 and FIG. 8 illustrate a region of a non-volatile memory device according to an implementation. Specifically, FIG. 7 and FIG. 8 each illustrate an enlarged cross-sectional view showing a portion “B” of FIG. 3. The non-volatile memory device illustrated in FIG. 7 and FIG. 8 has many similarities to the previous implementations, so the following description focuses mainly on the differences from the previous implementations. The non-volatile memory devices illustrated in FIGS. 7 and 8 may differ from the previous implementations in some respects in that they include a void formed within the barrier pattern 330.

Referring to FIG. 7 and FIG. 8, in a non-volatile memory device according to an implementation, a void may be positioned between the dummy semiconductor pattern 373 and the third substrate 310. That is, unlike what was described with reference to FIG. 6, in the non-volatile memory device according to the implementation, some regions between the third substrate 310 and the barrier pattern 330 may be filled with the barrier pattern 330, and the void may be positioned in remaining regions.

FIG. 7 and FIG. 8 may be example representations of positions where the void is formed within the barrier pattern 330. Referring to FIGS. 7 and 8, it is illustrated that the barrier pattern 330 is positioned along an outer surface of the dummy semiconductor pattern 373 and an inner surface of the third substrate 310, a void is positioned therebetween, and some barrier patterns 330 are also positioned above and below the void. As shown in FIG. 7, the void may have a trapezoidal shape in which a width along the horizontal direction (e.g., the first direction X or the second direction Y in FIGS. 7 and 8) gradually narrows as it gets closer to the second substrate 210 within the barrier pattern 330 in a cross-sectional view. The void may have an elongated elliptical shape along the third direction Z within the barrier pattern 330 in a cross-sectional view, as illustrated in FIG. 8.

However, FIGS. 7 and 8 illustrate examples of positions where voids are formed within the barrier pattern 330, and voids may be formed at various positions between the third substrate 310 and the dummy semiconductor pattern 373. In an example, a void may be formed in a process of forming the barrier pattern 330. For example, voids may be formed at various positions between the dummy semiconductor pattern 373 and the third substrate 310 according to process equipment, process conditions, etc. for forming the barrier pattern 330.

For example, in a process of forming the barrier pattern 330, an aspect ratio of the film formed may vary according to the process equipment or process conditions used. In this case, if the aspect ratio of the film formed is smaller than a space between the third substrate 310 and the dummy semiconductor pattern 373, the barrier pattern 330 may be formed in a portion of the area between the third substrate 310 and the dummy semiconductor pattern 373, and voids may be positioned in a remaining portion. For example, even if the aspect ratio of the film being formed is sufficiently high, a void may be formed between the dummy semiconductor pattern 373 and the third substrate 310 according to a difference in process time or a density of the film being formed. In an example, the void may be intentionally formed to be positioned in a certain region within the barrier pattern 330.

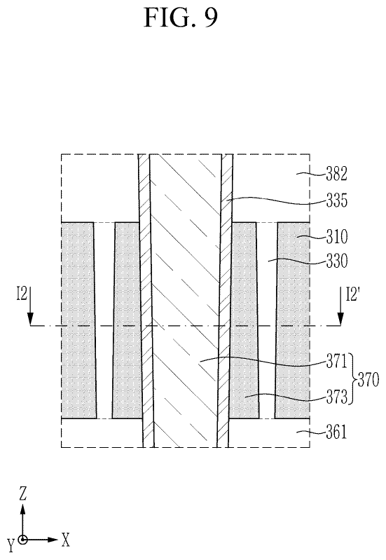

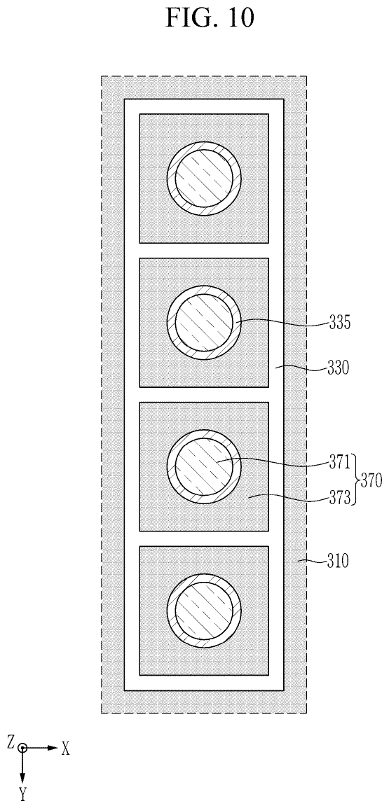

FIG. 9 and FIG. 10 illustrate a region of a non-volatile memory device according to an implementation. Specifically, FIG. 9 illustrates an enlarged cross-sectional view of a portion “B” of FIG. 3, and

FIG. 10 illustrates a top plan view showing a region of a non-volatile memory device according to an implementation. FIG. 10 illustrates a top plan view taken along a line II-II′ of FIG. 9. The non-volatile memory device illustrated in FIG. 9 and FIG. 10 has many similarities to the previous implementations, so the following description focuses mainly on the differences from the previous implementations. The non-volatile memory device illustrated in FIGS. 9 and 10 may differ in some respects from the preceding implementations in that it further includes an insulating liner 335 surrounding the through electrode 371.

Referring to FIGS. 9 and 10, a non-volatile memory device according to an implementation may include the insulating liner 335 surrounding a side surface of a through electrode 371. The insulating liner 335 may be conformally positioned along a side surface of the through electrode 371. The insulating liner 335 may be positioned between the through electrode 371 and the dummy semiconductor pattern 373 in a region where the through electrode 371 and the dummy semiconductor pattern 373 overlap in the horizontal direction. In the region where the through electrode 371 and the dummy semiconductor pattern 373 overlap in the horizontal direction, the insulating liner 335 may be surrounded on an outer surface by the dummy semiconductor pattern 373.

The insulating liner 335 may include an insulating material. For example, the insulation liner 335 may include at least one of a silicon oxide (SiO₂), a silicon nitride (SiN_{X}), or a silicon oxynitride (SiON), but the present disclosure is not limited thereto.

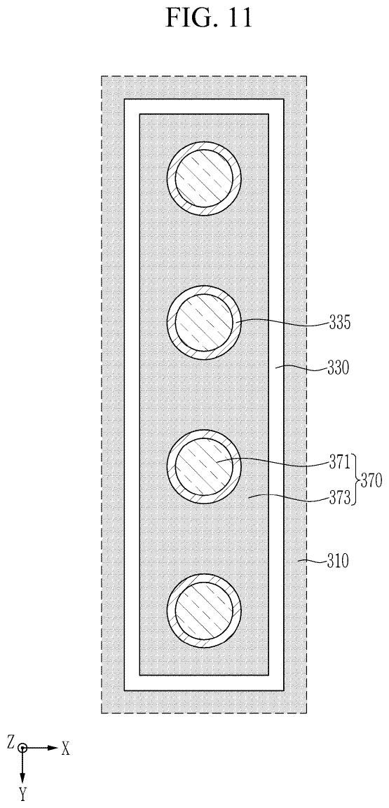

FIG. 11 illustrates a region of a non-volatile memory device according to an implementation. Specifically, FIG. 11 illustrates a top plan view showing a region of a non-volatile memory device according to an implementation. FIG. 11 illustrates a top plan view taken along a line II-II′ of FIG. 9. The non-volatile memory device illustrated in FIG. 11 has many similarities to the previous implementations, so the following description focuses mainly on the differences from the previous implementations. The non-volatile memory device illustrated in FIG. 11 may differ from the previous implementations in some respects in that the through electrodes 371 extend through a single dummy semiconductor pattern 373 formed integrally.

Referring to FIG. 11, a non-volatile memory device according to an implementation may include the insulating liner 335 surrounding a side surface of a through electrode 371. The insulating liner 335 is the same as the insulating liner 335 described with reference to FIGS. 9 and 10, so a detailed description will be omitted.

As illustrated in FIG. 11, in a non-volatile memory device, when the through electrodes 371 are positioned adjacent to each other in the horizontal direction, the insulating liner 335 may surround each side surface of the through electrodes 371. Unlike in the previous implementations, in a non-volatile memory device according to an implementation, one dummy semiconductor pattern 373 may be penetrated by the through electrodes 371. Referring to FIG. 11, when the through electrodes 371 are positioned adjacent to each other, the adjacent through electrodes 371 may extend through a single dummy semiconductor pattern 373 formed integrally in the third direction Z.

In an implementation, the barrier pattern 330 may surround an outer surface of the dummy semiconductor pattern 373. In an implementation, the barrier pattern 330 may not be positioned between two adjacent through electrodes 371. In an implementation, even if the barrier pattern 330 is not positioned between two adjacent through electrodes 371, each of the through electrodes 371 may be electrically isolated from each other by the insulating liner 335.

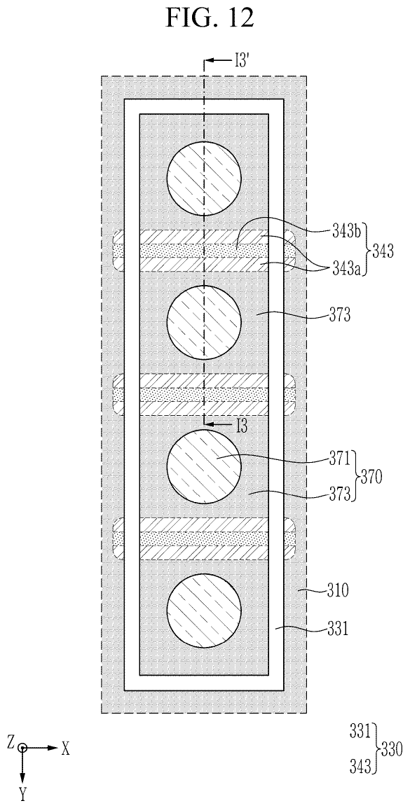

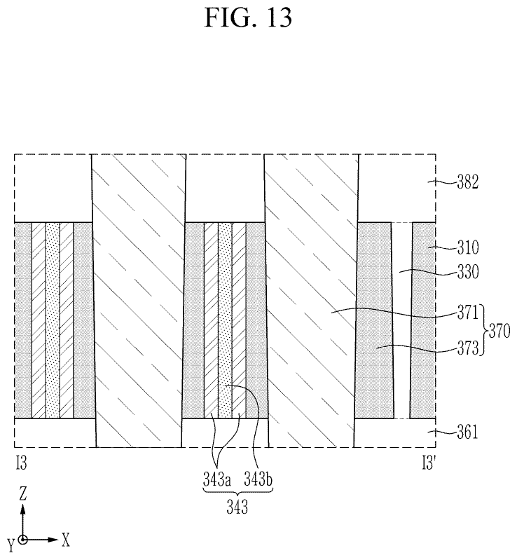

FIG. 12 and FIG. 13 illustrate a region of a non-volatile memory device according to an implementation. FIG. 12 illustrates a top plan view showing a region of a non-volatile memory device according to an implementation, and

FIG. 13 illustrates a cross-sectional view taken along a line I3-I3′ of FIG. 10. The non-volatile memory device illustrated in FIG. 12 and FIG. 13 has many similarities to the previous implementations, so the following description focuses mainly on the differences from the previous implementations. The non-volatile memory devices illustrated in FIGS. 12 and 13 may differ in some respects from the preceding implementations in that they include a semiconductor pattern in some regions of the barrier pattern 330.

Referring to FIGS. 12 and 13, in a non-volatile memory device according to an implementation, the barrier pattern 330 may include a first barrier pattern 331 surrounding an outer periphery of a through structure 370 and a second barrier pattern 343 positioned between a plurality of dummy semiconductor patterns 373 included in one through structure 370.

Specifically, as illustrated in FIG. 12 and FIG. 13, in a non-volatile memory device according to an implementation, when a plurality of through electrodes 371 and the dummy semiconductor patterns 373 surrounding each of the through electrodes 371 are positioned adjacent to each other in the through structure 370, the first barrier pattern 331 may surround an outer surface of the through structure 370, and the second barrier pattern 343 may be positioned between the dummy semiconductor patterns 373.

In an implementation, the first barrier pattern 331 may include an insulating material. A specific structure and included materials of the first barrier pattern 331 are the same as the barrier pattern 330 described in the previous implementations, so a detailed description will be omitted.

In an implementation, the second barrier pattern 343 may include a plurality of semiconductor patterns 343a and 343b, each of which includes a semiconductor material. In an implementation, the first semiconductor pattern 343a and the second semiconductor pattern 343b may be doped with different types of impurities. In an implementation, the first semiconductor pattern 343a may be doped with a first type of conductive impurity, and the second semiconductor pattern 343b may be doped with a second type of conductive impurity, which is different from that of the first. For example, the first semiconductor pattern 343a may be doped by a p type impurity, and the second semiconductor pattern 343b may be doped by a n type impurity. For example, each of the semiconductor patterns 343a and 343b may be formed by, but is not limited to, an ion implantation process (IIP).

Specifically, referring to FIGS. 12 and 13, each of the semiconductor patterns 343a and 343b may extend in the first direction X and the third direction Z between the dummy semiconductor patterns 373. An upper surface of each of the semiconductor patterns 343a and 343b may be positioned at a same level as that of an upper surface of the dummy semiconductor pattern 373, and a lower surface of each of the semiconductor patterns 343a and 343b may be positioned at a same level as that of an lower surface of the dummy semiconductor pattern 373.

Referring to FIGS. 12 and 13, the semiconductor patterns 343a and 343b may be alternately arranged between the second barrier patterns 343 along a direction in which the through electrodes 371 are arranged (for example, the second direction Y in FIGS. 12 and 13). Referring to FIGS. 12 and 13, the second barrier pattern 343 may include one first semiconductor pattern 343a and two second semiconductor patterns 343b positioned at opposite sides of one first semiconductor pattern 343a. Referring to FIGS. 12 and 13, two second semiconductor patterns 343b may be positioned spaced apart from each other with the first semiconductor pattern 343a provided therebetween.

In a structure such as that illustrated in FIG. 12 and FIG. 13, the second barrier pattern 343 positioned between two through electrodes 371 may prevent charges from crossing the second barrier pattern 343 to another adjacent through electrode 371 by a potential barrier positioned at a boundary between a p-type semiconductor region and an n-type semiconductor region, and thus, adjacent through electrodes 371 may be electrically separated from each other.

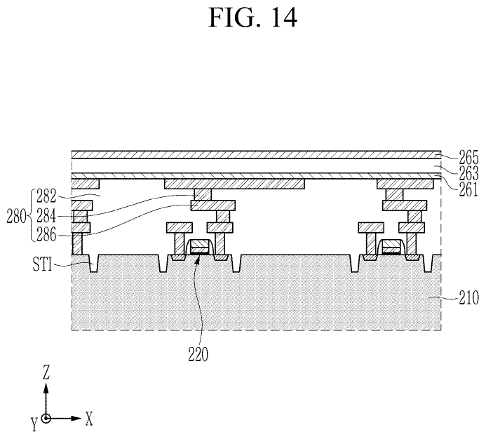

FIG. 14 to FIG. 23 illustrate process cross-sectional views for describing a manufacturing method for a non-volatile memory device according to an implementation.

What is illustrated in FIG. 14 may be the first circuit region 201, as described with reference to FIGS. 1 to 3. As illustrated in FIG. 14, the first circuit elements 220 and the second wiring portion 280 may be formed on the second substrate 210.

First, a device isolation pattern STI may be formed around a region where the first circuit elements 220 are to be formed on the second substrate 210 to separate the first circuit elements 220, and then the first circuit elements 220 may be positioned on the second substrate 210. In an implementation, the first circuit elements 220 may each include a source/drain electrode, a gate insulating layer, a gate electrode, and a gate spacer. Photo and etching processes, ion implantation processes, etc. may be performed to form the first circuit elements 220 on the second substrate 210.

Next, a second wiring portion 280 may be formed on the first circuit element 220. First, the wiring insulating layer 282 covering the first circuit elements 220 may be positioned on the second substrate 210. Thereafter, a portion of the wiring insulation layer 282 may be etched by a photo and etching process, and then a conductive material may be deposited to form the contact via 284 and the wiring layer 286. In FIG. 14, the wiring insulating layer 282 may be depicted as being a single layer, but the wiring insulation layer 282 may be formed of multiple layers. For example, by depositing the wiring insulating layer 282 and then patterning it to form the contact via 284 and the wiring layer 286, a process may be performed multiple times to form the second wiring portion 280 as illustrated in FIG. 14. Next, the interlayer insulating layers 261 and 263 and an interface insulating layer may be positioned on the wiring insulating layer 282. In an implementation, some of processes for forming the interlayer insulating layers 261 and 263 and processes for forming the interface insulating layers 265 may be omitted. During a process of forming the second wiring portion 280, the interlayer insulating layers 261 and 263, and the interface insulating layer 265, a chemical mechanical polishing (CMP) process may be performed to flatten an upper surface.

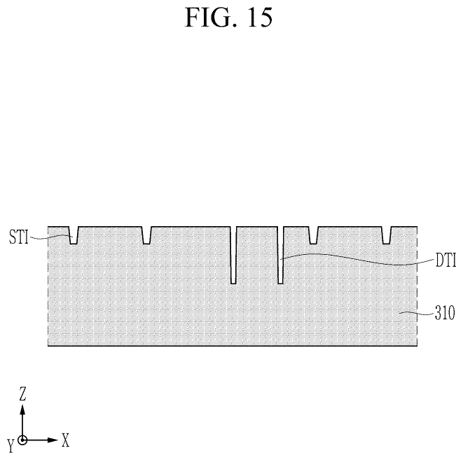

What are sequentially illustrated in FIGS. 15 to 18 may be a process of forming the second circuit region 202, as described with reference to FIGS. 1 to 3, during the manufacturing process of a non-volatile memory device according to an implementation. In an implementation, an order in which the process of forming the first circuit region 201 and the process of forming the second circuit region 202 are performed is not limited. For example, the first circuit region 201 and the second circuit region 202 may be processed on separate lines, respectively, and then connected to each other in a process of bonding the second substrate 210 and the third substrate 310. However, the implementation is not limited thereto, and the first circuit region 201 and the second circuit region 202 may be formed sequentially within a single process.

First, as illustrated in FIG. 15, a portion of the third substrate 310 may be etched to form a device isolation pattern STI and an isolation trench DTI. For example, after forming a mask pattern that exposes a region where the device isolation pattern STI and the isolation trench DTI are to be formed in some regions of the third substrate 310, a dry etching process may be performed to form the device isolation pattern STI and the isolation trench DTI.

The device isolation pattern STI may be formed around regions where the first circuit elements 220 are to be formed. The isolation trench DTI may be formed in a region where the barrier pattern 330 described with reference to FIGS. 1 to 3 is positioned. In an implementation, the isolation trench DTI may be formed to a deeper depth compared to the device isolation pattern STI. In an implementation, the isolation trench DTI may be formed to a narrow width compared to the device isolation pattern STI. However, the implementation is not limited thereto, and the device isolation pattern STI and the isolation trench DTI may have substantially a same width.

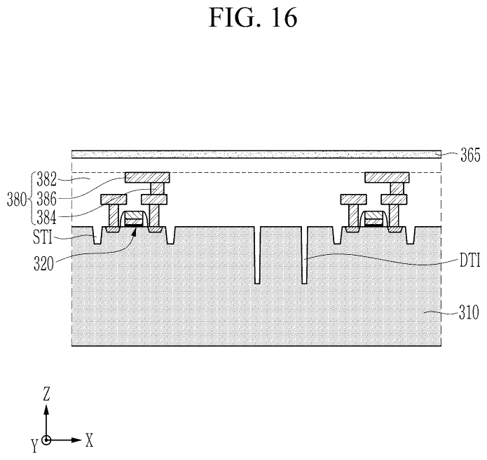

As illustrated in FIG. 16, the second circuit elements 320 and the third wiring portions 380 may be positioned on the third substrate 310 on which the device isolation pattern STI and the isolation trench DTI are formed

First, interiors of the device isolation pattern STI and the isolation trench DTI may be filled with an insulating material. In an implementation, the isolation trench DTI may have a relatively large aspect ratio

In an implementation, the isolation trench DTI may have a larger aspect ratio compared to the device isolation pattern STI. For example, a depth of the isolation trench DTI may be greater than or equal to about 4 μm, and a width may be less than or equal to about 200 nm.

In an implementation, a process of filling the interior of the isolation trench DTI with an insulating material may be performed by selecting a process that allows a film to be well formed even in an interior of a trench having a relatively large aspect ratio. For example, the process of filling the interior of the isolation trench DTI with an insulating material may be performed by atomic layer deposition (ALD). In a case of the atomic layer deposition method, a film may be conformally formed in units of one atomic layer on the substrate, so the film may be uniformly formed even inside a trench having a large aspect ratio, such as an isolation trench DTI according to an implementation.

In an implementation, the process of filling an insulating material within the device isolation pattern STI may be performed together with the process of filling an insulating material within the isolation trench DTI, or may be performed separately.

Next, the second circuit elements 320 may be positioned on the third substrate 310, and the interface insulating layer 365 and the third wiring portion 380 covering the second circuit elements 320 may be formed. The process of forming the second circuit elements 320, the third wiring portion 380, and the interface insulating layer 365 on the third substrate 310 is similar to the process of forming the first circuit element 220, the second wiring portion 280, the interlayer insulating layers 261 and 263, and the interface insulating layer 265 described above, and accordingly, a detailed description thereof will be omitted.

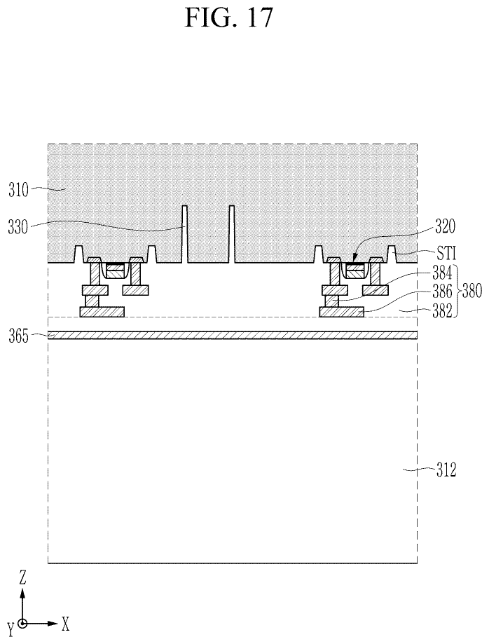

Next, a process of etching a portion of a lower region of the third substrate 310 may be performed. First, as illustrated in FIG. 17, a carrier substrate 312 may be attached to an upper surface of the third substrate 310. First, an upper surface of the interface insulating layer 365 may be positioned such that it faces one surface of the carrier substrate 312, and then the one surface of the carrier substrate 312 and the upper surface of the interface insulating layer 365 may be attached to each other. In this case, the third substrate 310 may be rotated such that the upper surface of the interface insulating layer 365 and the one surface of the carrier substrate 312 face each other. Although not explicitly shown in FIG. 17, an adhesive member may be additionally positioned between the interface insulating layer 365 and the carrier substrate 312.

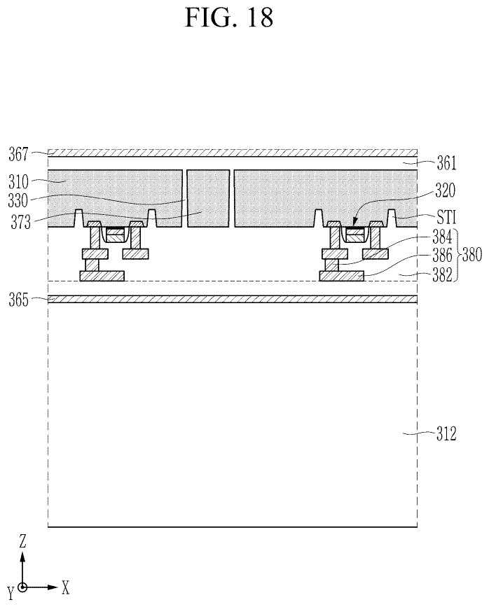

Next, as illustrated in FIG. 18, a portion of a lower region of the third substrate 310 may be removed. A process of removing a portion of the third substrate 310 may be performed by grinding and/or chemical mechanical polishing processes.

In an implementation, the process of removing the lower portion of the third substrate 310 may be performed so as to have an appropriate thickness by considering an operating voltage of the second circuit element 320 and a breakdown voltage of the third substrate 310. In the process of removing the lower portion of the third substrate 310, the third substrate 310 may be controlled to have a thickness that is greater than or equal to about 4 μm.

In an implementation, the process of removing a portion of a region of the third substrate 310 may be performed using the isolation trench DTI as an etch stop layer. In other words, the process of removing a portion of the third substrate 310 may be performed until the isolation trench DTI is completely exposed on the etched lower surface of the third substrate 310.

In an implementation, the dummy semiconductor pattern 373 separated from the third substrate 310 and the barrier pattern 330 positioned between the dummy semiconductor pattern 373 and the third substrate 310 may be formed as the isolation trench DTI is exposed on the lower surface of the third substrate 310 by a process of removing a portion of the third substrate 310. Thereafter, the interlayer insulating layer 361 and the interface insulating layer 367 may be sequentially disposed on the lower surface of the third substrate 310.

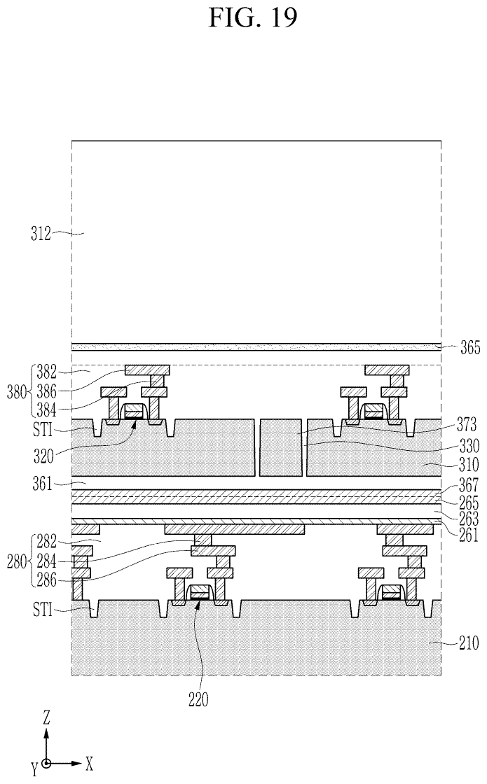

As illustrated in FIG. 19, the second substrate 210 and the third substrate 310 may be bonded to each other. Specifically, the interface insulating layer 367 positioned on the lower surface of the third substrate 310 and the interface insulating layer 265 positioned on the upper surface of the second substrate 210 may be positioned to face each other, and then facing surfaces of the two interface insulating layers 367 and 265 may be attached. Although not explicitly shown in FIG. 19, an adhesive member may be additionally positioned between the two interface insulating layers 367 and 265.

In the process of bonding the second substrate 210 and the third substrate 310 to each other, a process of aligning the two substrates 210 and 310 may be further performed. For example, after the second substrate 210 and the third substrate 310 are positioned such that the first align key 288 (see FIG. 1) and the second align key 388 (see FIG. 1) described with reference to FIG. 1 overlap each other vertically, facing surfaces of the two interface insulating layers 367 and 265 may be attached.

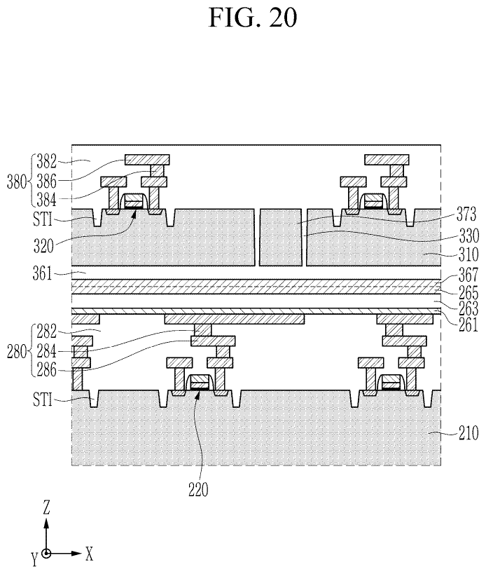

As illustrated in FIG. 20, the carrier substrate 312 may be removed from the third substrate 310, and a portion of the upper portion of the wiring insulating layer 382 and the interface insulating layer 365 may be removed. When a portion of the wiring insulating layer 382 is etched, an etching process may be controlled such that the contact via 384 or the wiring layer 386 is not exposed to the outside.

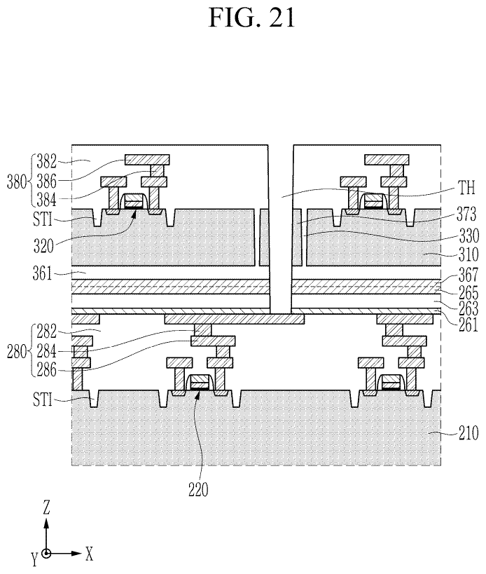

Next, the through electrode 371 extending through the dummy semiconductor pattern 373 in the third direction Z may be formed. First, as illustrated in FIG. 21, a through hole TH extending through the wiring insulating layer 282, the dummy semiconductor pattern 373, and the insulating layers 261, 263, 265, 361, and 367 in the third direction Z may be formed by a photo and etching process. In an implementation, the wiring insulating layer 282, the dummy semiconductor pattern 373, and the insulating layers 261, 263, 265, 361, and 367 may be sequentially etched by a dry etching process.

When forming the through hole TH, if a substrate is exposed to a metal included in a wire, etc., the substrate may be contaminated by the metal, and in this case, characteristics of circuit elements positioned on the substrate may deteriorate. According to an implementation, in a process of forming the through hole TH, the third substrate 310 may be separated from the dummy semiconductor pattern 373 and the wiring layer 286 exposed to the through hole TH by the barrier pattern 330, and thus, reliability of the non-volatile memory device according to the implementation may be improved. In addition, according to an implementation, in the process of forming the through electrode 371, there is no need to perform an additional process for protecting the third substrate 310 (e.g., a process of protecting the substrate by covering a sidewall of the through hole with an insulating material), so the process of manufacturing the non-volatile memory device according to the implementation may be performed efficiently.

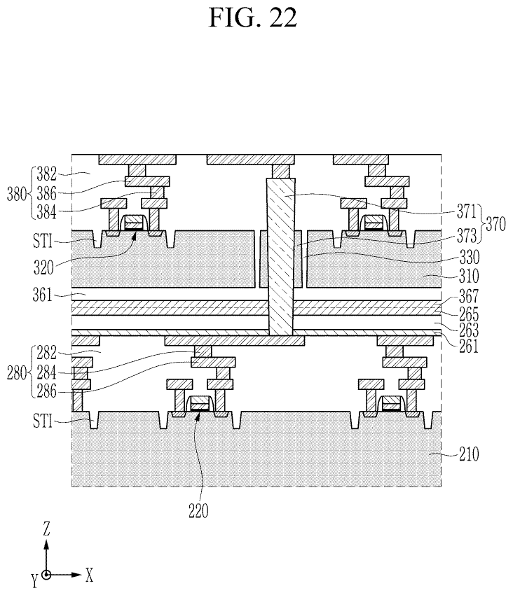

Next, as illustrated in FIG. 22, the through hole TH may be filled with a conductive material to form the through electrode 371. In this case, a conductive material may be positioned on some regions of an upper surface of the wiring insulating layer 382, and a chemical mechanical polishing process may be additionally performed to remove the conductive material positioned on the upper surface of the wiring insulation layer 382. In an implementation, a first end of the through electrode 371 may be connected to the wiring layer 286 or the contact via 284 connected to the first circuit element 220.

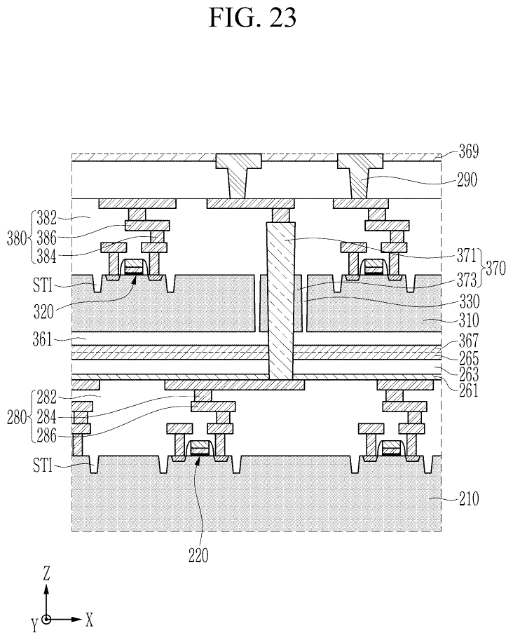

As illustrated in FIG. 23, by performing photo and etching processes on the third substrate 310, the additional wiring insulation layer 382, the contact via 384, and the wiring layers 386 may be formed, and then the second bonding portion 290 and the interface insulating layer 369 may be formed. The second bonding portion 290 may be connected to the through electrode 371 or the second circuit element 320 through the contact via 384 and/or the wiring layers 386. Referring to FIG. 23, a second end of the through electrode 371 is depicted as being connected to the second bonding portion 290, but the second end of the through electrode 371 may also be connected to the second circuit element 320 (see FIG. 1).

Next, as illustrated in FIG. 24, the first substrate 110 on which the cell region 100 is formed may be bonded onto the third substrate 310. The gate stack structure 120, the channel structure CH, the first wiring portion 180, and the first bonding portion 190 may be positioned on the first substrate 110. The process of forming the cell region 100 may be performed separately from the process of forming the circuit region 200. In an implementation, after forming the gate stack structure 120, the channel structure CH, the first wiring portion 180, and the first bonding portion 190 on the first substrate 110, the first substrate 110 and the third substrate 310 may be positioned such that upper surfaces of the first bonding portion 190 and the interface insulating layer 193 and upper surfaces of the second bonding portion 290 and the interface insulating layer 369 are in contact, and then the upper surface of the first bonding portion 190 and the upper surface of the interface insulating layer 193 may be attached to the upper surface of the second bonding portion 290 and the upper surface of the interface insulating layer 369, respectively, and thus the non-volatile memory device described with reference to FIGS. 1 to 5 may be manufactured.

According to an implementation, as described with reference to FIGS. 15 to 23, an isolation trench DTI having a relatively narrow width may be formed around a region where the through electrode 371 is to be formed, and by using the trench, the dummy semiconductor pattern 373 separated from the third substrate 310 and the through electrode 371 extending through the pattern may be formed. The through electrode 371 may be electrically separated from the third substrate 310 by the dummy semiconductor pattern 373.

In contrast, when forming the through electrode 371, there are cases where an isolation trench DTI having a width wider than a width along the horizontal direction of the through electrode 371 is formed, then the trench is filled with an insulating layer, and the through electrode 371 is formed to extend through a portion of the insulating layer. In this case, if an insulating layer is formed inside a wide-width isolation trench DTI by atomic vapor deposition, a process time may become excessively long and a process cost may increase. An insulating layer may be deposited inside the wide-width isolation trench DTI by chemical vapor deposition, which has a faster deposition rate than that of an atomic vapor deposition method, but in this case, the insulating layer filling the isolation trench DTI may have a lower step coverage than that of an insulating layer formed by an atomic vapor deposition method, and thus voids may be formed inside the isolation trench DTI. A width of the isolation trench DTI may be formed sufficiently larger to prevent voids from forming inside the isolation trench DTI, but in this case, a size of the non-volatile memory device according to the implementation may become excessively large.

In the case where the isolation trench DTI is formed with a relatively narrow width around a region where the through electrode 371 is formed, as in the implementation described with reference to FIGS. 14 to 24, and so as to surround the through electrode 371, the through electrode 371 may be efficiently formed in a narrow region, compared to a case where the isolation trench DTI is formed widely (for example, with a width wider than the width in the horizontal direction of the through electrode 371), and thus reliability of the process for manufacturing a non-volatile memory device may be improved and a size of the memory device may be reduced.

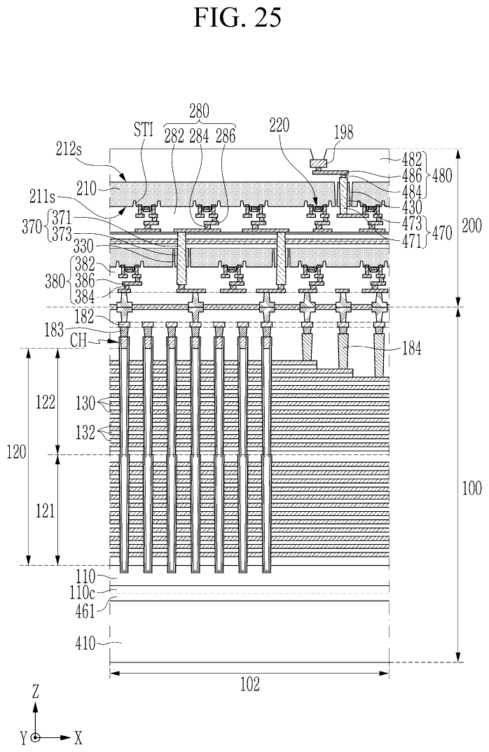

FIG. 25 illustrates a partial cross-sectional view schematically showing a non-volatile memory device according to an additional implementation. The non-volatile memory device illustrated in FIG. 25 has many similarities to the previous implementations so the following description focuses mainly on the differences from the previous implementations. A non-volatile memory device according to an implementation may differ from the previous implementations in some respects in that it further includes a fourth substrate 410 positioned in the cell region 100 and a through structure 470 positioned in the circuit region 200 and extending through the second substrate 210.

The non-volatile memory device illustrated in FIG. 25 may have a shape similar to that in which the non-volatile memory device is positioned such that an upper surface of the outer insulating layer 110c of the non-volatile memory device illustrated in FIG. 1 faces an upper surface of the fourth substrate 410, and then the upper surface of the external insulating layer 110c and the upper surface of the fourth substrate 410 are attached. In an implementation, the fourth substrate 410 may include a semiconductor layer including a semiconductor material. For example, the fourth substrate 410 may be formed of silicon, germanium, silicon-germanium, silicon on insulator, or germanium on insulator. An interlayer insulating layer 461 may be positioned between the upper surface of the fourth substrate 410 and the outer insulating layer 110c. For example, the interlayer insulating layer 461 may include at least one of a silicon oxide (SiO₂), a silicon nitride (SiN_{X}), or a silicon oxynitride (SiON). Although not explicitly shown in FIG. 25, an adhesive material may be additionally positioned between the interlayer insulating layer 461 and the outer insulating layer 110c.

In a non-volatile memory device according to an implementation, the second substrate 210 may include a first surface 211s on which the first circuit elements 220 are positioned and a second surface 212s facing the first surface 211s. The first surface 211s may include an active area. The first surface may be positioned closer to the cell region 100 compared to the second surface 212s. In an implementation, a fourth wiring portion 480 may be positioned on the second surface 212s of the second substrate 210. Unlike what has been described with reference to FIGS. 1 to 24, in a non-volatile semiconductor device according to an implementation, the input/output pad 198 may be positioned in the circuit region 200 rather than the cell region 100. Specifically, the input/output pad 198 may be positioned on the second surface 212s of the second substrate 210.

The fourth wiring portion 480 may include a wiring layer 486, contact vias 484, and a wiring insulating layer 482 surrounding them. The input/output pad 198 may be connected to the through electrode 471 described later through the wiring layer 486 and the contact vias 484. The input/output pad 198 may be partially surrounded by the wiring insulating layer 482. At least a portion of the upper surface of the input/output pad 198 may be exposed to the outside.

The through structure 470 may be positioned within the second substrate 210. The through structure 470 may include a dummy semiconductor pattern 473 surrounded by the second substrate 210 and positioned spaced apart from the second substrate 210, and a through electrode 471 extending through the dummy semiconductor pattern 473 in the third direction Z. A non-volatile memory device according to an implementation may further include a barrier pattern 430 positioned between the second substrate 210 and the dummy semiconductor pattern 473. The specific structure, function, etc. of the dummy semiconductor pattern 473 and the barrier pattern 430 are the same as or similar to those of the dummy semiconductor pattern 373 and the barrier pattern 330 described with reference to FIGS. 1 to 24, so a detailed description thereof will be omitted.

In an implementation, the through electrode 471 may extend along the third direction Z. In an implementation, the through electrode 471 may extend along the third direction Z by extending through the dummy semiconductor pattern 473. A first end of the through electrode 471 may be connected to the input/output pad 198 through the contact vias 484 and/or the wiring layers 486. A second end of the through electrode 471 may be connected to the first circuit element 220 through the contact vias 284 and/or the wiring layers 286. The through electrode 471 may extend through the dummy semiconductor pattern 473 to electrically connect the first circuit element 220 positioned on the first surface 211s of the second substrate 210 to the input/output pad 198 positioned on the second surface 212s of the second substrate 210. In an implementation, the dummy semiconductor pattern 473 may be electrically separated from the second substrate 210 by the barrier pattern 430, and the through electrode 471 may be surrounded by the dummy semiconductor pattern 473. Accordingly, the through electrode 471 may be electrically separated and insulated from the second substrate 210.

Except for the above-described details regarding the structure and function of the through electrode 471, details are the same as or similar to the through electrode 371 described with reference to FIGS. 1 to 24, so a detailed description thereof will be omitted.

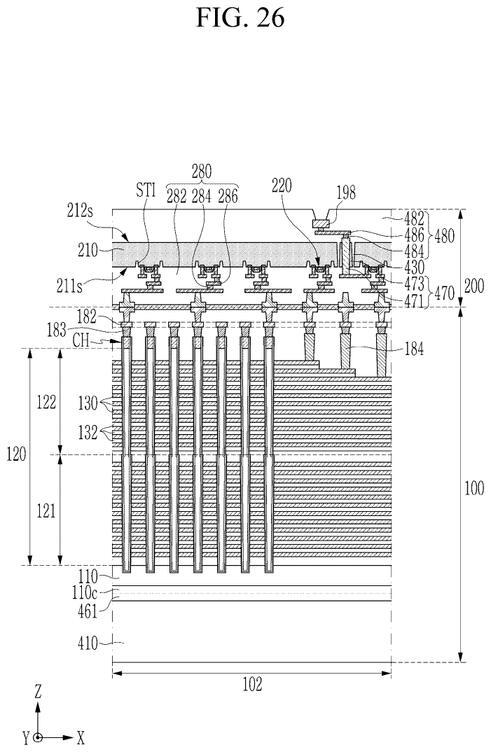

FIG. 26 illustrates a partial cross-sectional view schematically showing a non-volatile memory device according to an additional implementation. The non-volatile memory device illustrated in FIG. 26 has many similarities to the previous implementations so the following description focuses mainly on the differences from the previous implementations. The non-volatile memory device according to the implementation may differ in some respect from the preceding implementations in that the circuit region 200 includes a single substrate. In the previous implementations, circuit elements may be positioned on each of two substrates, and in the present implementation, circuit elements may be positioned on the single substrate.

Specifically, referring to FIG. 26, a non-volatile memory device according to an implementation may include a first substrate 110 on which a plurality of memory cell structures are positioned, and a second substrate 210 on which first circuit elements 220 are positioned. A third substrate 310 such as that described with reference to FIGS. 1 to 25 may not be positioned between the first substrate 110 and the second substrate 210.

In an implementation, the input/output pad 198 may be positioned on the second surface 212s of the second substrate 210. In an implementation, a point where the through electrode 471 extends through the second substrate 210 to electrically connect the first circuit element 220 and the input/output pad 198 is the same as that described with reference to FIG. 25, so a detailed description thereof will be omitted.

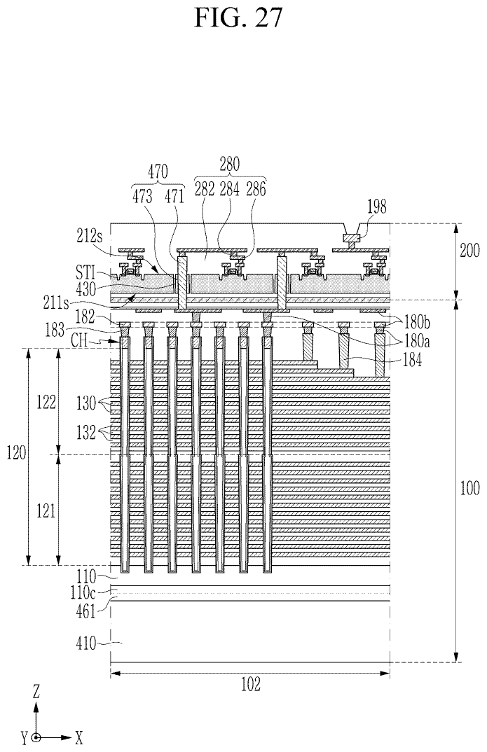

FIG. 27 illustrates a partial cross-sectional view schematically showing a non-volatile memory device according to an additional implementation. The non-volatile memory device illustrated in FIG. 27 has many similarities to the previous implementations so the following description focuses mainly on the differences from the previous implementations. In a non-volatile memory device according to an implementation, positions of the first circuit elements 220 may be partially different from those in the preceding implementations.

Referring to FIG. 27, in a non-volatile memory device according to an implementation, the second substrate 210 may include a first surface 211s and a second surface 212s, opposite to the first surface 211s, and the first circuit elements 220 may be positioned on the second surface 212s of the second substrate 210. The second surface 212s may be positioned further away from the cell region 100 compared to the first surface 211s. That is, unlike the non-volatile memory device described with reference to FIG. 25 and FIG. 26 in which the first circuit elements 220 are positioned on the first surface 211s, in the implementation, the first circuit elements 220 may be positioned on the second surface 212s.

In an implementation, the through electrode 471 may extend along the third direction Z. In an implementation, the through electrode 471 may extend along the third direction Z by extending through the dummy semiconductor pattern 473. A first end of the through electrode 471 may be connected to the first circuit element 220 through the contact vias 284 and/or the wiring layers 286. A second end of the through electrode 471 may be connected to at least one of a plurality of memory cells positioned in the cell region 100 through contact vias 180a and/or connection wires 180b. Specifically, the second end of the through electrode 371 may be connected to the gate stack structure 120 and/or the channel structure CH positioned in the cell region 100 through the contact vias 180a and/or the connecting wires 180b.

In the implementation described with reference to FIGS. 25 and 26, unlike the implementation in which the input/output pad 198 is connected to the first circuit element 220 through the through electrode 471, in the implementation, the input/output pad 198 may be connected to the first circuit element 220 through the contact vias 284 and/or wiring layers 286. An example of an electronic system including the aforementioned non-volatile memory device will be described in detail.

FIG. 28 schematically illustrates an electronic system including a non-volatile memory device according to an implementation.

Referring to FIG. 28, the electron system 1000 according to an implementation may include a semiconductor device 1100 and a controller 1200 electrically connected to the semiconductor device 1100. The semiconductor device 1110 of FIG. 28 may be a non-volatile memory device described with reference to FIGS. 1 to 24. The electronic system 1000 may be a storage device including one or a plurality of semiconductor devices 1100 or an electronic device including the storage device. For example, the electronic system 1000 may be a solid state drive (SSD) device including one or the plurality of semiconductor devices 1100, a universal serial bus (USB), a computing system, a medical device, or a communication apparatus.

The semiconductor device 1100 may be a non-volatile memory device, and may be, for example, a NAND flash memory device described with reference to FIG. 1 to FIG. 24. The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including a bitline BL, a common source line CSL, a word line WL, first and second gate upper lines UL1 and UL2, and first and second gate lower lines LL1 and LL2, and a memory cell string CSTR between the bitline BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT positioned between the lower transistors LT1 and LT2 and the upper transistors UT1 and UT2. A number of lower transistors LT1 and LT2 and a number of upper transistors UT1 and UT2 may be variously modified according to another implementation.

In an implementation, the lower transistors LT1 and LT2 may include ground selective transistors, and the upper transistors UT1 and UT2 may include string selective transistors. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connecting wire 1115 extending from the first structure 1100F to the second structure 1100S. The bitline BL may be electrically connected to the page buffer 1120 through a second connecting wire 1125 extending to the second structure 1100S in the first structure 1100F.

In the first structure 1100F, the decoder circuit 1110 and the page buffer 1120 may execute a control operation on at least one memory cell transistor selected from among the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connecting wire 1135 extending from the first structure 1100F to the second structure 1100S. The input/output connection wire 1135 may be formed of a connection structure 188 (see FIG. 1) of a non-volatile memory device described with reference to FIGS. 1 to 24.

The controller 1200 may include a processor 1210, a NAND controller 1220, and a host interface 1230. According to another implementation, the electronic system 1000 may include a plurality of semiconductor devices 1100, and in this case, the controller 1200 may control the semiconductor devices 1100.

The processor 1210 may control an overall operation of the electron system 1000 including the controller 1200. The processor 1210 may operate according to predetermined firmware, and may access the semiconductor devices 1100 by controlling the NAND controller 1220. The NAND controller 1220 may include a NAND interface 1221 that processes communication with the semiconductor devices 1100. A control command for controlling the semiconductor device 1100, data to be recorded in the memory cell transistor MCT of the semiconductor device 1100, and data to be read from the memory cell transistor MCT of the semiconductor device 1100 may be transmitted through the NAND interface 1221. The host interface 1230 may provide a communication function between the electronic system 1000 and an external host. When a control command is received from an external host through the host interface 1230, the processor 1210 may control the semiconductor devices 1100 in response to the control command.

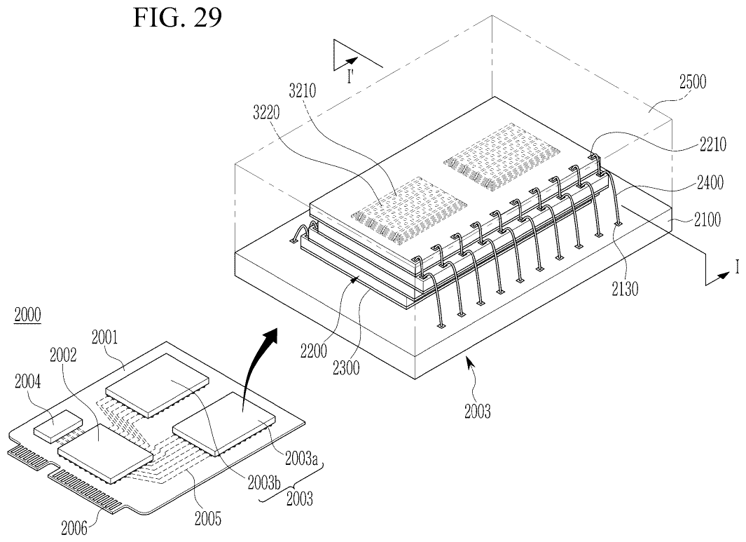

FIG. 29 illustrates a schematic perspective view showing an electronic system including a non-volatile memory device according to an implementation.

Referring to FIG. 29, an electronic system 2000 according to an implementation may include a main substrate 2001, a controller 2002 mounted on the main substrate 2001, one or more semiconductor packages 2003, and a DRAM 2004. The semiconductor package 2003 and the DRAM 2004 may be connected to the controller 2002 through a wiring pattern 2005 positioned on the main substrate 2001.

The main substrate 2001 may include a connector 2006 including a plurality of pins coupled to an external host. A number and disposition of the pins in the connector 2006 may vary depending on a communication interface between the electronic system 2000 and the external host. In an implementation, the electronic system 2000 may communicate with the external host according to any one of interfaces such as a universal flash storage (USB), a peripheral component interconnect express (PCI-Express), a serial advanced technology attachment (SATA), M-Phy for universal flash storage (UFS), and the like. In an implementation, the electronic system 2000 may operate with power supplied from an external host through the connector 2006. The electronic system 2000 may further include a power management integrated circuit (PMIC) that distributes power supplied from the external host to the controller 2002 and semiconductor package 2003.

The controller 2002 may record data in the semiconductor package 2003, or may read data from the semiconductor package 2003, and may improve an operation speed of the electronic system 2000.

The DRAM 2004 may be a buffer memory for buffering a speed difference between the semiconductor package 2003, which is a data storage space, and an external host. The DRAM 2004 included in the electronic system 2000 may also operate as a kind of cache memory, and may provide a space for temporarily storing data in the control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a semiconductor chip 2200 on the package substrate 2100, an adhesive layer 2300 disposed on a lower surface of each semiconductor chip 2200, a connecting structure 2400 that electrically connects the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 28. Each semiconductor chip 2200 may include a gate stack structure 4210 and a channel structure 4220. The semiconductor chip 2200 may include the non-volatile memory device described with reference to FIG. 1 to FIG. 24.

In an implementation, the connecting structure 2400 may be a bonding wire electrically connecting the input/output pad 2210 and the package upper pad 2130. Accordingly, the semiconductor chips 2200 may be electrically connected to each other by using a bonded wire method, and may be electrically connected to the package upper pad 2130 of the package substrate 2100 in each of the first and second semiconductor packages 2003a and 2003b. According to an implementation, the semiconductor chips 2200 may be electrically connected to each other by a connecting structure including a through silicon via (TSV) instead of the bonding wire connecting structure 2400 in each of the first and second semiconductor packages 2003a and 2003b.

In an implementation, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wire positioned on the interposer substrate.

FIG. 30 illustrates a schematic cross-sectional view of a semiconductor package according to an implementation. FIG. 30 illustrates an implementation of the semiconductor package 2003 of FIG. 29, and conceptually illustrates a region of the semiconductor package 2003 of FIG. 29 taken along a line I-I′.

Referring to FIG. 30, in the semiconductor package 2003, the package substrate 2100 may be a printed circuit board. The package substrate 2100 may include a package substrate body 2120, a package upper pad 2130 positioned on an upper surface of the package substrate body 2120, a package lower pad 2125 positioned on a lower surface of the package substrate body 2120 or exposed through a lower surface, and an internal wire 2135 electrically connecting the package upper pad 2130 and the package lower pad 2125 within the package substrate body 2120. The package upper pad 2130 may be electrically connected to the connecting structure 2400. The package lower pad 2125 may be connected to the wire pattern 2005 of the main substrate 2010 of the electronic system 2000 through a conductive connector 2800 as illustrated in FIG. 29.

In a semiconductor package 2003, each semiconductor chip 2200 may include a semiconductor substrate 4010, a first structure 4100 on the semiconductor substrate 4010, and a second structure 4200 bonded to a first structure 4100 by wafer bonding on the first structure 4100. The semiconductor chip 2200 may include the non-volatile memory device described with reference to FIG. 1 to FIG. 24.

The first structure 4100 may include a peripheral circuit region including a peripheral wire 4110 and a first junction structure 4150. Although not explicitly illustrated in FIG. 30, the peripheral circuit region in the semiconductor package (2003) according to the implementation may include two or more circuit regions positioned vertically, such as the first circuit region 201 (see FIG. 1) and the second circuit region 202 described with reference to FIGS. 1 to 24. In an implementation, two or more circuit regions positioned above and below may be bonded to each other in a wafer bonding manner, or may be formed sequentially within a single process. The second structure 4200 may include a common source line 4205, a gate stack structure 4210 between the common source line 4205 and the first structure 4100, a channel structure 4220 and a separating structure 4230 extending through the gate stack structure 4210, and a second junction structure 4250 electrically connected to the word line (reference numeral WL in FIG. 28, hereinafter the same) of each of the channel structure 4220 and the gate stack structure 4210. For example, the second junction structure 4250 may be electrically connected to the channel structure 4220 and the word line WL through a bit line 4240 electrically connected to the channel structure 4220 and a gate connecting wire electrically connected to the word line WL, respectively. The first junction structure 4150 of the first structure 4100 and the second junction structure 4250 of the second structure 4200 may be bonded while contacting each other. A bonded portion of the first junction structure 4150 and the second junction structure 4250 may be formed of, e.g., copper (Cu).

A non-volatile memory device according to an implementation may include a first circuit region 201 positioned on the second substrate 210, and a second circuit region 202 positioned on the third substrate 310. A non-volatile memory device according to an implementation may include a through electrode 371 extending through the third substrate 310, and the first circuit element 220 included in the first circuit region 201 may be connected to a second circuit element 320 included in the second circuit region 202, or memory cells included in the cell region 100, through the through electrode 371.

In an implementation, the through electrode 371 may be electrically isolated from the third substrate 310 by the dummy semiconductor pattern 373 and the barrier pattern 330 surrounding the dummy semiconductor pattern 373. In this case, an electrical signal flowing through the through electrode 371 may be prevented from flowing to the second circuit element 320 through the third substrate 310, and thus reliability of the non-volatile memory device may be improved.

In addition, according to an implementation, the through electrode 371 extending through the third substrate 310 may be formed in a narrow area through a simple process, thereby improving reliability of a process for manufacturing a non-volatile memory device and reducing a size of the memory device.

Each of the semiconductor chips 2200 may further include an input/output pad 2210 and an input/output connecting wire 4265 under the input/output pad 2210. The input/output connecting wire 4265 may be electrically connected to a portion of the second junction structure 4250. The input/output connection wire 4265 may be formed of a connection structure 188 (see FIG. 1) of a non-volatile memory device described with reference to FIGS. 1 to 24.

In an implementation, a plurality of semiconductor chips 2200 in the semiconductor package 2003 may be electrically connected to each other by a connecting structure 2400 having a form of a bonding wire. As another example, the semiconductor chips 2200 or a plurality of portions constituting the semiconductor chips 2200 may be electrically connected by a connecting structure including the through silicon via (TSV).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A non-volatile memory device comprising:
a first substrate;
a plurality of memory cell structures on the first substrate;
a second substrate facing the first substrate in a first direction perpendicular to a surface of the first substrate;
a first circuit element on the second substrate;
a third substrate between the first substrate and the second substrate;
a second circuit element on the third substrate; and
a through structure comprising
a dummy semiconductor pattern that is surrounded by the third substrate and spaced apart from the third substrate, and
a through electrode extending through the dummy semiconductor pattern in the first direction,
wherein the through electrode has a first end connected to the first circuit element, and a second end connected to the second circuit element or at least one of the memory cell structures.

2. The non-volatile memory device of claim 1, wherein
the through electrode has a side surface, a region of the side surface being in contact with the dummy semiconductor pattern, the region of the side surface horizontally overlapping the third substrate.

3. The non-volatile memory device of claim 1, wherein
the dummy semiconductor pattern has a thickness equal to a thickness of the third substrate, and the dummy semiconductor pattern includes a same semiconductor material as the third substrate.

4. The non-volatile memory device of claim 1, wherein
an air gap is between the third substrate and the through structure.

5. The non-volatile memory device of claim 1, wherein
a barrier pattern is between the third substrate and the through structure.

6. The non-volatile memory device of claim 5, wherein
the third substrate and the through structure are separated from each other by the barrier pattern.

7. The non-volatile memory device of claim 5, wherein
the barrier pattern includes:
an insulating material between an inner surface of the third substrate and an outer surface of the dummy semiconductor pattern; and
a void surrounded by the insulating material.

8. The non-volatile memory device of claim 5,
wherein the through structure comprises a plurality of dummy semiconductor patterns including the dummy semiconductor pattern,
wherein the barrier pattern is a first barrier pattern that surrounds a periphery of the through structure, and
wherein the non-volatile memory device comprises a second barrier pattern between the plurality of dummy semiconductor patterns, and
wherein the second barrier pattern includes a plurality of semiconductor patterns, the plurality of semiconductor patterns being arranged in a second direction, each of the plurality of semiconductor patterns being elongated in a third direction, the third direction being parallel to a surface of the third substrate and perpendicular to the second direction.

9. The non-volatile memory device of claim 8, wherein
the plurality of semiconductor patterns include a first semiconductor pattern, and include second semiconductor patterns at opposite sides of the first semiconductor pattern, and
wherein the second semiconductor patterns are doped with a first type of impurity, and the first semiconductor pattern is doped with a second type of impurity, and the first type of impurity is different from the second type of impurity.

10. The non-volatile memory device of claim 5, comprising
a wiring insulating layer on the third substrate and covering the second circuit element,
wherein the wiring insulating layer and the barrier pattern include a same insulating material.

11. The non-volatile memory device of claim 5, wherein
the barrier pattern is in contact with an outer surface of the dummy semiconductor pattern and an inner surface of the third substrate, and
a gap distance between the outer surface of the dummy semiconductor pattern and the inner surface of the third substrate is between 0 nm and 200 nm.

12. The non-volatile memory device of claim 1,
wherein the through structure includes:
a plurality of through electrodes arranged along a second direction parallel to a surface of the third substrate; and
dummy semiconductor patterns respectively surrounding side surfaces of the plurality of through electrodes,
wherein the dummy semiconductor patterns are spaced apart from each other.

13. The non-volatile memory device of claim 1,
wherein the through structure includes a plurality of through electrodes arranged along a second direction parallel to a surface of the third substrate, and
wherein the non-volatile memory device comprises insulating liners respectively surrounding side surfaces of the plurality of through electrodes, each of the insulating liners between the dummy semiconductor pattern and a respective through electrode of the plurality of through electrodes.

14. The non-volatile memory device of claim 13, wherein
the dummy semiconductor pattern forms an integral part and surrounds an outer surface of each of the insulating liners.

15. The non-volatile memory device of claim 1, wherein
the first circuit element is connected to a first power source, and
the second circuit element is connected to a second power source that has a voltage higher than a voltage of the first power source.

16. A non-volatile memory device comprising:
a first substrate;
a gate stack structure comprising interlayer insulating layers and gate electrodes stacked in an alternating fashion on a lower surface of the first substrate;
channel structures extending through the gate stack structure in a first direction perpendicular to the lower surface of the first substrate;
a first bonding portion below the channel structures and connected to at least one of the channel structures;
a second substrate facing the first substrate in the first direction;
a first circuit element on an upper surface of the second substrate;
a third substrate between the first substrate and the second substrate;
a second circuit element on the third substrate;
a second bonding portion on the second circuit element, the second bonding portion being in contact with the first bonding portion;
a through structure comprising a dummy semiconductor pattern spaced apart from the third substrate, and a through electrode extending through the dummy semiconductor pattern in the first direction and toward the upper surface of the second substrate; and
a barrier pattern extending through the third substrate in the first direction and surrounding a side surface of the through structure,
wherein the through electrode has a first end connected to the first circuit element and a second end connected to the second circuit element or at least one of the second bonding portions.

17. The non-volatile memory device of claim 16, wherein
the through electrode has a side surface, a region of the side surface being in contact with the dummy semiconductor pattern, the region of the side surface horizontally overlapping the third substrate.

18. The non-volatile memory device of claim 16, wherein
an air gap is between the third substrate and the through structure.

19. The non-volatile memory device of claim 16, wherein
the barrier pattern includes:
an insulating material between an inner surface of the third substrate and an outer surface of the dummy semiconductor pattern; and
a void surrounded by the insulating material.

20. An electronic system comprising:
a main substrate;
a non-volatile memory device on the main substrate; and
a controller electrically connected to the non-volatile memory device, the controller being on the main substrate,
wherein the non-volatile memory device comprises:
a first substrate;
a plurality of memory cell structures on the first substrate;
a second substrate facing the first substrate in a first direction perpendicular to a surface of the first substrate;
a first circuit element on the second substrate;
a third substrate between the first substrate and the second substrate;
a second circuit element on the third substrate; and
a through structure comprising
a dummy semiconductor pattern that is surrounded by the third substrate and spaced apart from the third substrate, and
a through electrode extending through the dummy semiconductor pattern in the first direction,
wherein the through electrode has a first end connected to the first circuit element and a second end connected to the second circuit element or at least one of the memory cell structures.
